(19) United States
(12) Patent Application Publication
(10) Pub. No.: US 2020/0203266 A1
(43) Pub. Date: Jun. 25, 2020

(54) SUBSTRATE, METHOD OF MANUFACTURING SUBSTRATE, AND ELECTRONIC DEVICE

(71) Applicant: FUJITSU LIMITED, Kawasaki-shi (JP)

(72) Inventors: Toshiki Iwai, Atsugi (JP); Taiji Sakai, Yokohama (JP)

(73) Assignee: FUJITSU LIMITED, Kawasaki-shi (JP)

(21) Appl. No.: 16/701,234

(22) Filed: Dec. 3, 2019

(30) Foreign Application Priority Data
Dec. 25, 2018 (JP) 2018-241529

(51) Int. Cl. H01L 23/498; H01L 21/48; H01L 23/15

(52) U.S. Cl. CPC H01L 23/49822; H01L 23/49866; H01L 24/16; H01L 23/15; H01L 21/486; H01L 21/4857

(57) ABSTRACT

A substrate includes: a glass layer having a first surface, a second surface opposite to the first surface, and a through hole penetrating between the first surface and the second surface; a metal layer provided in a first portion of the through hole, the first portion extending from the first surface and not reaching the second surface; and a conductive layer provided in a second portion of the through hole, coupled to the metal layer, and containing a resin and a conductive filler mixed with the resin, the second portion extending from the second surface and not reaching the first surface.

### CROSS-REFERENCE TO RELATED APPLICATION

This application is based upon and claims the benefit of priority of the prior Japanese Patent Application No. 2018-241529, filed on Dec. 25, 2018, the entire contents of which are incorporated herein by reference.

### FIELD

The embodiments discussed herein are related to a substrate, a method of manufacturing a substrate, and an electronic device.

### BACKGROUND

A technique for forming a through hole as a hole provided in a ceramic substrate, and a technique for laminating and bonding together a plurality of the ceramic substrates with a conductive paste to form a multilayer structure are known. A technique for forming an interlayer coupling material in a via hole provided in an electrically insulating substrate of a resin by a method such as conductive paste injection, filled plating, or conformal plating, and a technique for laminating a plurality of the electrically insulating substrates by heating and pressing to form a multilayer structure are also known.

Japanese Laid-open Patent Publication No. 4-42597 is an example of related art. Japanese Laid-open Patent Publication No, 2007-280997 is another example of related art.

### SUMMARY

According to an aspect of the embodiments, a substrate includes: a glass layer having a first surface, a second surface opposite to the first surface, and a through hole penetrating between the first surface and the second surface; a metal layer provided in a first portion of the through hole, the first portion extending from the first surface and not reaching the second surface; and a conductive layer provided in a second portion of the through hole, coupled to the metal layer, and containing a resin and a conductive filler mixed with the resin, the second portion extending from the second surface and not reaching the first surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram for describing an example of a substrate according to a first embodiment;

FIG. 2 is a diagram for describing an example of a multilayer substrate according to the first embodiment;

FIG. 3 is a diagram for describing a first example of a substrate of a different structure and a multilayer substrate including the substrate;

FIG. 4 is a diagram for describing a second example of a substrate of a different structure and a multilayer substrate including the substrate;

FIG. 5 is a diagram (part 1) for describing an example of a substrate according to a second embodiment;

FIGS. 6A to 6C are diagrams (part 2) for describing an example of the substrate according to the second embodiment;

FIGS. 7A and 7B are diagrams (part 3) for describing an example of the substrate according to the second embodiment;

FIGS. 8A to 8C are diagrams (part 1) for describing an example of a method of forming the substrate according to the second embodiment;

FIGS. 9A to 9C are diagrams (part 2) for describing an example of the method of forming the substrate according to the second embodiment;

FIGS. 10A to 10C are diagrams (part 3) for describing an example of the method of forming the substrate according to the second embodiment;

FIG. 11 is a diagram (part 1) for describing a multilayer substrate according to the second embodiment;

FIG. 12 is a diagram (part 2) for describing a multilayer substrate according to the second embodiment;

FIG. 13 is a diagram (part 3) for describing a multilayer substrate according to the second embodiment;

FIGS. 14A to 14C are diagrams for describing an example of stress analysis results of the substrate according to the second embodiment;

FIGS. 15A to 15C are diagrams for describing an example of stress analysis results of a substrate of a different structure;

FIG. 16 is a diagram for describing a first modification of the substrate according to the second embodiment;

FIG. 17 is a diagram for describing a second modification of the substrate according to the second embodiment;

FIGS. 18A to 18E are diagrams for describing a third modification of the substrate according to the second embodiment;

FIG. 19 is a diagram for describing a fourth modification of the substrate according to the second embodiment;

FIGS. 20A and 20B are diagrams for describing a fifth modification of the substrate according to the second embodiment;

FIG. 21 is a diagram for describing an example of an electronic device according to a third embodiment; and

FIG. 22 is a diagram for describing an example of an electronic apparatus according to a fourth embodiment.

### DESCRIPTION OF EMBODIMENTS

In some cases, a glass layer having a thermal expansion coefficient close to that of silicon (Si) or the like used for an electronic component such as a semiconductor chip to be mounted over a substrate may be used as a material for the substrate. For example, a conductive material is formed in a through hole provided in a glass layer by a known method such as conductive paste injection, filled plating, or conformal plating, and a via is formed in the glass layer. In this case, however, a via having a low resistance may not be obtained, or snapping of the via may occur due to cracks generated in the glass layer due to stress, so that sufficient conduction reliability may not be obtained through the via in the substrate.

In one aspect, a substrate having high conduction reliability may be provided.

### First Embodiment

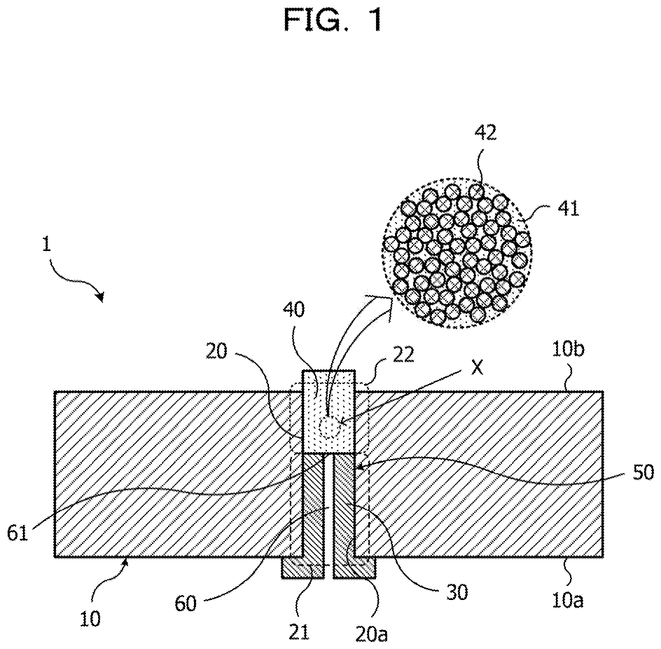

FIG. 1 is a diagram for describing an example of a substrate according to a first embodiment. FIG. 1 schematically illustrates a cross-sectional view of a principal part of the substrate.

A substrate 1 illustrated in FIG. 1 includes a glass layer 10, a through hole 20, a metal layer 30, and a conductive layer 40.

The glass layer 10 serves as a core layer of the substrate 1. For the glass layer 10, various glass materials such as alkali-free glass, soda glass, and quartz glass may be used. Although the illustration is omitted herein, a wiring layer of a predetermined pattern is formed using a conductive material such as copper (Cu) over one surface 10a or the one surface 10a and the other surface 10b of the glass layer 10.

The through hole 20 is provided so as to penetrate between the surface 10a and the surface 10b of the glass layer 10. For example, the glass layer 10 is provided with a cylindrical through hole 20 penetrating therethrough. The through hole 20 may have a tapered shape (truncated cone shape) in which the inner diameter thereof becomes larger or smaller from the surface 10a toward the surface 10b in the glass layer 10. The through hole 20 may have a Hyperboloid shape in which a middle portion between the surface 10a and the surface 10b is constricted, a drum shape in which the middle portion is swollen, or the like. Although the illustration is omitted herein, a planar shape of an opening (an opening in the surface 10a or the surface 10b or an opening in a plane therebetween) of the through hole 20 is not limited to a circular shape, and may be another planar shape such as an elliptical shape.

The metal layer 30 is provided in the through hole 20 of the glass layer 10. The metal layer 30 is provided in at least a portion 21 of the through hole 20 extending from the surface 10a and not reaching the surface 10b in the glass layer 10. The metal layer 30 may have a portion provided over the surface 10a of the glass layer 10 in addition to over an inner wall 20a of the through hole 20. The metal layer 30 functions as a part of a via 50 (Through Glass Via, TGV) that electrically couples the surface 10a to the surface 10b in the glass layer 10. The metal layer 30 is provided, for example, in the form of a conformal via over the inner wall 20a of the portion 21 of the through hole 20. In this case, as illustrated in FIG. 1, the substrate 1 may have a structure in which a space 60 formed inside the metal layer 30 is left as a cavity, or may have a structure in which, although the illustration is omitted herein, a filling material such as resin is injected into the space 60. Various metal materials may be used for the metal layer 30. For example, Cu or a material containing Cu is used for the metal layer 30. The metal layer 30 is formed by, for example, a plating method. The metal layer 30 may be provided in the form of a filled via injected into the portion 21 of the through hole 20.

The conductive layer 40 is provided in the through hole 20 of the glass layer 10. The conductive layer 40 is provided at least in a portion 22 of the through hole 20 extending from the surface 10b and not reaching the surface 10a in the glass layer 10. The conductive layer 40 may be provided so as to protrude from the through hole 20, that is, may be provided such that an upper end position of the conductive layer 40 is positioned above the surface 10b of the glass layer 10. The conductive layer 40 functions as a part of the via 50 (TGV) that electrically couples the surface 10a to the surface 10b in the glass layer 10. As schematically illustrated in an enlarged view of a portion X of FIG. 1, the conductive layer 40 includes a resin 41 and a conductive filler 42 mixed with the resin 41. The conductive layer 40 is formed by, for example, supplying a conductive paste (also referred to as a “resin composition”) containing the resin 41 in an uncured state and the conductive filler 42 into the through hole 20 provided with the metal layer 30 by using a method such as printing, application, or dripping, and curing the resin 41.

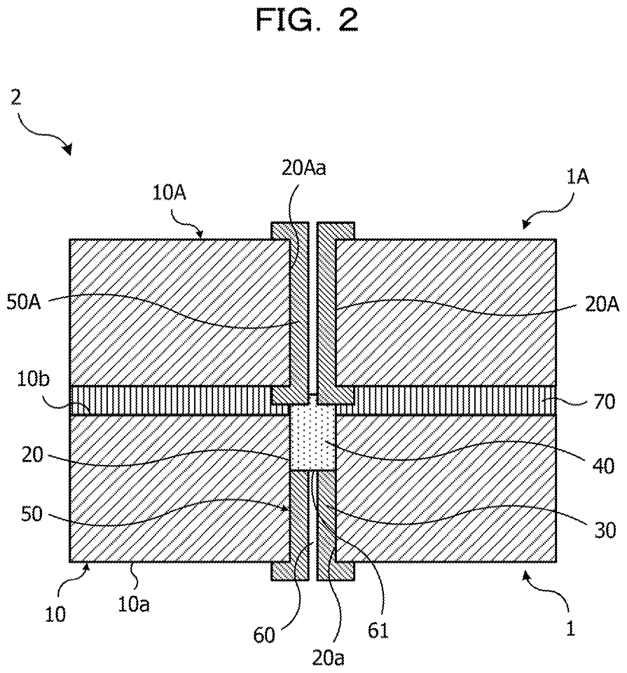

For example, in the substrate 1, a conductive layer 40 having a higher thermal expansion coefficient than the glass layer 10, the metal layer 30, and an adhesive layer (adhesive layer 70 in FIG. 2) used when the substrate 1 is laminated with and bonded to another substrate is used as the conductive layer 40. For example, in the substrate 1, a conductive layer 40 containing a conductive filler 42 larger than an opening 61 of the space 60 surrounded by the metal layer 30 is used as the conductive layer 40. For example, in the through hole 20, the metal layer 30 is provided in the portion 21 at a depth equal to or more than a half of the depth of the through hole 20 (height or thickness of the glass layer 10) and, in a case where a wiring layer is provided over the glass layer 10, equal to or less than a depth obtained by subtracting the thickness of the wiring layer from the depth of the through hole 20.

The metal layer 30 and the conductive layer 40 provided in the through hole 20 of the glass layer 10 function as the via 50, that is, the TGV of the substrate 1, which penetrates between the surface 10a and the surface 10b in the glass layer 10 and electrically couples the surface 10a to the surface 10b.

For example, the substrate 1 having the structure described above is laminated with and bonded with one or more other substrates by being heated and pressed to form a multilayer structure.

FIG. 2 is a diagram for describing an example of a multilayer substrate according to the first embodiment. FIG. 2 schematically illustrates a cross-sectional view of a principal part of the multilayer substrate.

FIG. 2 illustrates, as an example, a multilayer substrate 2 in which another substrate 1A is laminated over the substrate 1 described above (above the surface 10b side of the glass layer 10) via the adhesive layer 70. The substrate 1A includes a glass layer 10A serving as a core layer, a through hole 20A provided in the glass layer 10A, and a via (referred to as a “conformal via”) 50A provided over an inner wall 20Aa of the through hole 20A. A resin such as an epoxy resin is used for the adhesive layer 70. The adhesive layer 70 may contain, in addition to the resin, an insulating filler such as glass filler or glass cloth mixed with a resin.

The multilayer substrate 2 is formed by laminating the substrate 1 and the substrate 1A described above with the adhesive layer 70 interposed therebetween and heating and pressing (hot-pressing) the laminated substrates under predetermined conditions of temperature and pressure, for example, a temperature of 200° C. and a pressure of 30 kg/cm². Such a method of forming the multilayer substrate 2 is also referred to as a batch lamination process. By the hot pressing, the conductive layer 40 of the via 50 of the substrate 1 and the conformal via 50A (conductive coupling portion) of the substrate 1A are joined to each other, and thus the via 50 and the conformal via 50A are electrically coupled to each other.

Although the multilayer substrate 2 in which the one other substrate 1A is laminated over the substrate 1 is described as an example herein, two or more other substrates may be laminated over the substrate 1 with the adhesive layer 70 therebetween as described above.

Various electronic components, for example, a semiconductor chip such as a large scale integration (LSI) chip are to be mounted over the multilayer substrate 2 described above formed by using the substrate 1.

In the multilayer substrate 2 described above, the glass layer 10 and the glass layer 10A are used as core layers of the substrate 1 and the substrate 1A, respectively. With the glass layer 10 and the glass layer 10A, relatively high flatness may be realized. The glass layer 10 and the glass layer 10A have thermal expansion coefficients dose to or equivalent to those of materials of a semiconductor chip to be mounted over the multilayer substrate 2, such as Si and silicon dioxide (SiO₂). Wiring layers of fine patterns and pitches may be formed over the glass layer 10 and the glass layer 10A due to the high flatness thereof. Since the difference in thermal expansion coefficient between the glass layers 10 and 10A and the semiconductor chip to be mounted over the multilayer substrate 2 is small, the difference in thermal deformation between the multilayer substrate 2 and the semiconductor chip may be suppressed. Therefore, breakage of the junction (bumps of solder or the like) between the multilayer substrate 2 and the semiconductor chip caused by the difference in thermal deformation between the multilayer substrate 2 and the semiconductor chip may be suppressed. Further, since the difference in thermal deformation between the multilayer substrate 2 and the semiconductor chip and the breakage of the junction therebetween may be suppressed, the size of the junction may be also reduced. As a result, in the multilayer substrate 2 including the glass layer and the glass layer 10A, the size of the semiconductor chip to be mounted may be reduced and the density of the semiconductor chip to be mounted may be increased.

In the substrate 1 which may be used for the multilayer substrate 2 as described above, the metal layer 30 is provided in a part (portion 21) of the through hole 20 of the glass layer 10, and the conductive layer 40 is provided in the other part (portion 22) of the through hole 20 to form the via 50. In the substrate 1, the conductive layer 40 of the via 50 containing the resin 41 and the conductive filler 42 is used. By adopting such a structure, in the substrate 1, stress (also referred to as internal stress, thermal stress, strain, or the like) generated in the glass layer 10 may be relieved, and low-resistance electrical coupling between the conductive layer 40 and the metal layer 30 may be realized even when heat is applied to the substrate 1 and the multilayer substrate 2 including the substrate 1.

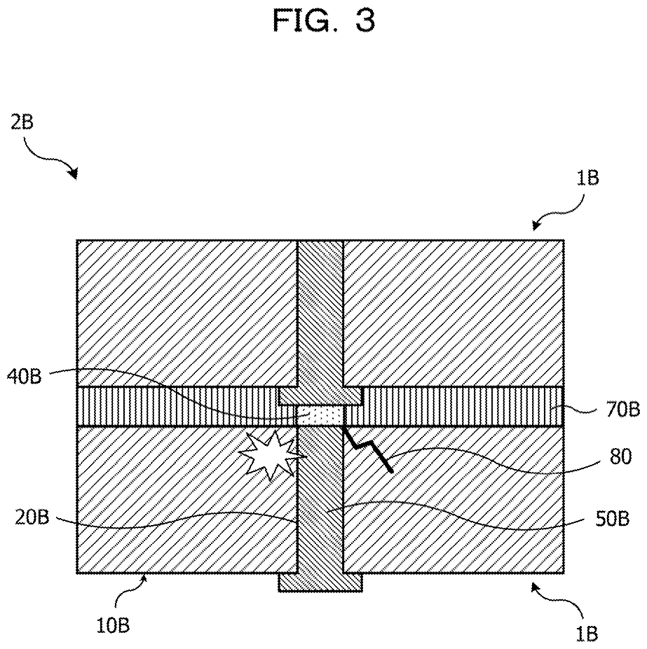

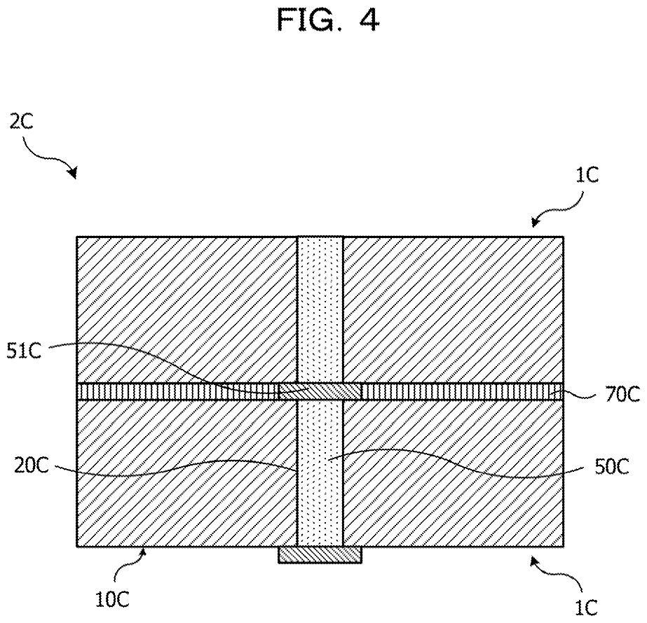

For comparison, an example of a substrate of a different structure and a multilayer substrate including the substrate will be described with reference to FIGS. 3 and 4.

FIG. 3 is a diagram for describing a first example of a substrate of a different structure and a multilayer substrate including the substrate. FIG. 3 schematically illustrates a cross-sectional view of a principal part of an example of the multilayer substrate.

FIG. 3 illustrates an example of a multilayer substrate 2B in which two substrates 1B each including a via (referred to as a “filled via”) 50B formed by injecting a metal material such as Cu into the entirety of a through hole 208 provided in a glass layer 10B are laminated with an adhesive layer 70B therebetween. The filled vias 50B of the two substrates 18 are coupled to each other via a conductive layer 40B formed from a conductive paste. The multilayer substrate 2B is formed by, for example, a batch lamination process in which hot pressing is performed under predetermined conditions in a state in which a conductive paste to be the conductive layer 40B and the adhesive layer 70B are interposed between the substrates 18.

Heat is applied to the multilayer substrate 28 illustrated in FIG. 3 at the time of mounting the semiconductor chip after formation of the multilayer substrate 2B (for example, at the time of solder reflow), at the time of test after the mounting (for example, at the time of reliability test), at the time of using the multilayer substrate 2B, or the like, in addition to the time of formation of the multilayer substrate 2B by hot pressing. The filled via 50B formed from a metal material such as Cu has a higher thermal expansion coefficient and a higher elastic modulus than the glass layer 10B. Therefore, when heat is applied, a relatively high stress is likely to be generated around the through hole 20B of the glass layer 10B in the substrate 18 due to differences in thermal expansion coefficient and elastic modulus between the glass layer 10B and the filled via 508 formed in the through hole 208.

The stress generated in the glass layer 10B tends to concentrate near an edge of the through hole 20B, for example, near an edge of the through hole 20B where the glass layer 10B, the filled via 50B, the conductive layer 40B, and the adhesive layer 70B that are formed from different materials are in contact with each other. As a result, in the substrate 1B, a crack 80 may be generated in the glass layer 10B as starting from the vicinity of the edge of the through hole 20B. The crack 80 may reach the filled via 50B and cause snapping of the filled via 50B or an increase in the resistance of the filled via 50B, and when a wiring layer is provided over the glass layer 10B, the crack may reach the wiring layer and cause snapping or an increase in the resistance.

Further, in the multilayer substrate 2B, a conductive layer 40B having a thermal expansion coefficient lower than that of the adhesive layer 70B is used as the conductive layer 40B for coupling the filled vias 50B to each other. Therefore, when heat is applied, the conductive layer 40B is pulled by the adhesive layer 70B that thermally expands more, so that a force in the direction in which the conductive layer 40B is peeled off from the filled vias 50B is likely to be generated. As a result, in the multilayer substrate 2B, adhesion between the conductive layer 40B and the filled vias 50B is weakened, or snapping between the conductive layer 40B and the filled vias 508 occurs, and the coupling resistance therebetween may increase or the coupling failure therebetween may occur.

FIG. 4 is a diagram for describing a second example of a substrate of a different structure and a multilayer substrate including the substrate. FIG. 4 schematically illustrates a cross-sectional view of a principal part of an example of the multilayer substrate.

FIG. 4 illustrates an example of a multilayer substrate 2C in which two substrates 1C each including a conductive paste via (referred to as a “paste via”) 50C formed from a conductive paste is formed in the entirety of a through hole 20C provided in a glass layer 10C are laminated with an adhesive layer 70C therebetween. An end of the paste via 50C is covered with a metal layer 51C. The multilayer substrate 2C is formed by, for example, laminating another glass layer 10C in which the paste via 50C is formed in the through hole 20C over the substrate 1C including the paste via 50C whose both ends are covered with metal layers 51C with the adhesive layer 70C between the two substrates 1C and hot-pressing the substrates 1C under predetermined conditions.

The paste via 50C of the substrate 1C is formed by injecting a conductive paste into the through hole 20C of the glass layer 10C. As described above, as compared with the filled via 50B described above formed from a metal material such as Cu, the paste via 50C formed from the conductive paste has a high thermal expansion coefficient but has a low elastic modulus. Therefore, in the substrate 1C, when heat is applied, stress generated around the through hole 20C in the glass layer 10C may be suppressed due to the low elastic modulus even if the paste via 50C is thermally expanded relatively greatly.

However, in the paste via 50C formed by injecting the conductive paste into the entirety of the through hole 20C, the resistance is more likely to increase than in the filled via 508 formed by injecting a metal material such as Cu into the entirety of the through hole 20B. Further, when forming the conductive paste, there may be a case where sufficient contact between conductive fillers is not achieved in the through hole 20C or a case where the conductive paste does not sufficiently go into the through hole 20C, depending on the opening size and depth of the through hole 20C, the filler content and viscosity of the conductive paste, and the like. Both cases serve as factors of causing an increase in the resistance of the paste via 50C and a failure in the coupling via the paste via 50C.

In contrast, in the substrate 1 (FIGS. 1 and 2) described above, the metal layer 30 is provided in a part (portion 21) of the through hole 20, and the conductive layer 40 containing the resin 41 and the conductive filler 42 is provided in the other part (portion 22) of the through hole 20, thereby forming the via 50.

The conductive layer 40 containing the resin 41 and the conductive filler 42 has a lower elastic modulus than the metal layer 30 formed from a metal material such as Cu. In the substrate 1, the conductive layer 40 having such a relatively low elastic modulus goes into the inside (portion 22) of the through hole 20, so that stress generated around the through hole 20 is relieved. As a result of the stress being relieved around the through hole 20, generation of cracks in the glass layer 10 may be suppressed, and snapping of and an increase in the resistance of the via 50 caused by cracks, and snapping of and an increase in the resistance of a wiring layer in the case where the wiring layer is provided over the glass layer 10, are suppressed.

Further, the conductive layer 40 containing the resin 41 and the conductive filler 42 has a higher thermal expansion coefficient than the glass layer 10 and the metal layer 30. In the substrate 1, since the conductive layer 40 having such a relatively high thermal expansion coefficient goes into the through hole 20, the conductive layer 40 is pressed against the metal layer 30 in the through hole 20 due to thermal expansion of the conductive layer 40 when heat is applied. As a result of the conductive layer 40 being pressed against the metal layer 30, an increase in the coupling resistance therebetween and occurrence of coupling failure therebetween may be suppressed.

When the thermal expansion coefficient of the conductive layer 40 is set to be higher than that of the adhesive layer 70 in addition to the glass layer 10 and the metal layer 30, the force of pressing the conductive layer 40 against the metal layer 30 in the through hole 20 is increased due to the difference in thermal expansion between the conductive layer 40 and the adhesive layer 70. This is because generation of such a force that the conductive layer 40 is pulled by the adhesive layer 70 to peel off from the metal layer 30 caused by thermal expansion is suppressed, and the conductive layer 40, which thermally expands more than the adhesive layer 70, is pressed against the metal layer 30 in the through hole 20. As a result of this, an increase in the coupling resistance between and occurrence of coupling failure between the conductive layer 40 and the metal layer 30 may be effectively suppressed.

When the conductive layer 40 contains the conductive filler 42 larger than the opening 61 of the space 60 surrounded by the metal layer 30, the conductive layer 40 hardly passes through the opening 61 to the space 60, and is blocked in the vicinity of an end portion of the metal layer 30. Thus, a strong force of pressing the conductive layer 40, which thermally expands when heat is applied to the substrate 1, against the end portion of the metal layer 30 in the through hole 20 may be obtained, and an increase in the coupling resistance between and occurrence of coupling failure between the conductive layer 40 and the metal layer 30 may be effectively suppressed.

In the through hole 20, the via 50 is formed, for which an increase in the resistance is suppressed as compared with a case where a via is formed by filling the through hole 20 with only the conductive layer 40, by providing the metal layer 30 formed from a metal material such as Cu together with the conductive layer 40 containing the resin 41 and the conductive filler 42. For example, in the through hole 20, the metal layer 30 is provided in the portion 21 at a depth equal to or more than a half of the depth of the through hole 20 from the surface 10b to the surface 10a in the glass layer 10 and equal to or less than a depth obtained by subtracting the thickness of the wiring layer provided over the glass layer 10 from the depth of the through hole 20. Thus, stress generated in the glass layer 10 may be relieved by the conductive layer 40, and the occurrence of cracks therein may be suppressed, and further, by including not only the conductive layer 40 but also a certain amount of the metal layer 30, an increase in the resistance as the via 50 may be suppressed.

The substrate 1 having high conduction reliability and the multilayer substrate 2 including the substrate 1 may be realized in which cracks in the glass layer 10, snapping caused by the cracks, and the like may be suppressed, an increase in the coupling resistance between and occurrence of coupling failure between the conductive layer 40 and the metal layer 30 may be suppressed, and further an increase in the resistance of the via 50 may be suppressed.

### Second Embodiment

An example of a substrate having a structure as described in the first embodiment will be described as a second embodiment.

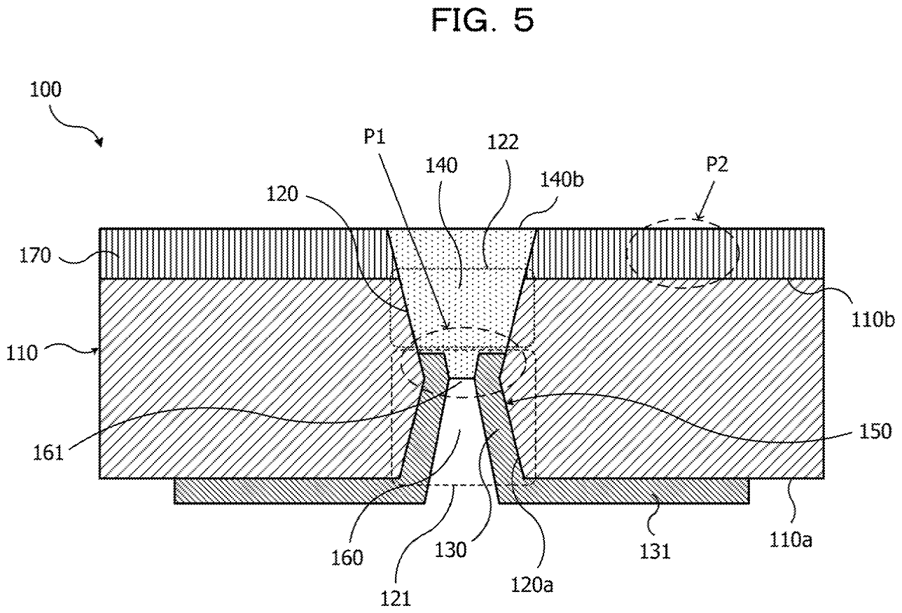

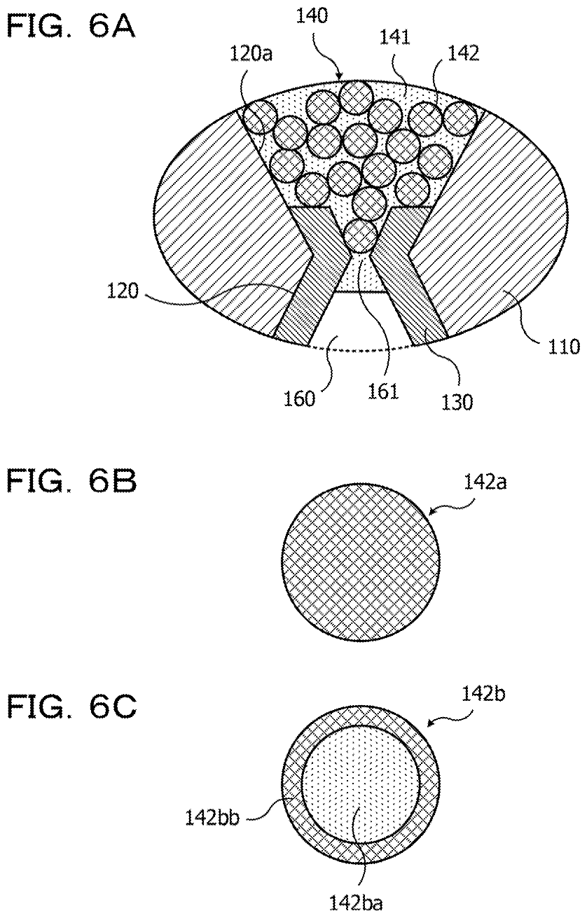

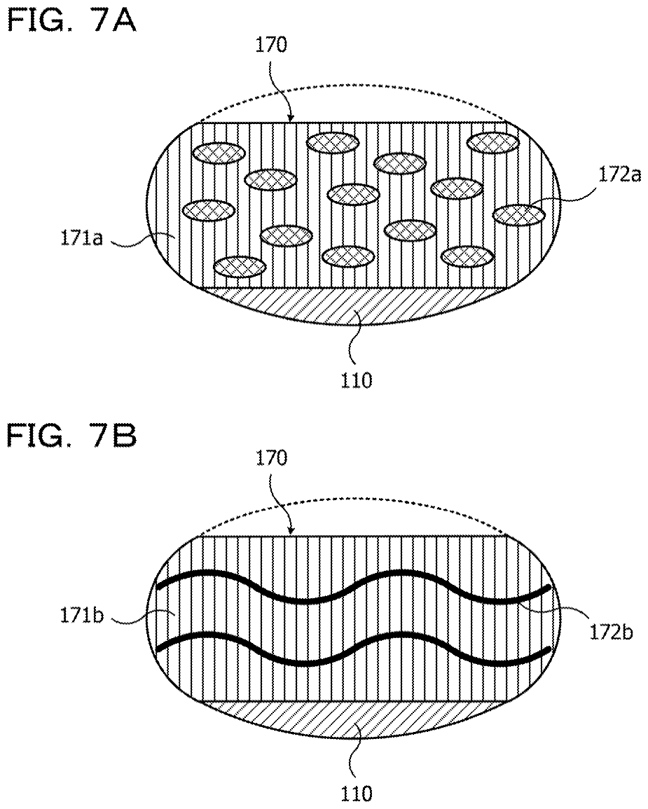

FIGS. 5 to 7B are diagrams for describing an example of a substrate according to the second embodiment. FIG. 5 schematically illustrates a cross-sectional view of a principal part of an example of the substrate. FIG. 6A schematically illustrates an enlarged sectional view of an example of a portion P1 of FIG. 5, and FIG. 6B and FIG. 6C each schematically illustrate an example of a conductive filler. FIGS. 7A and 7B each schematically illustrate an enlarged sectional view of an example of a portion P2 of FIG. 5.

A substrate 100 illustrated in FIG. 5 includes a glass layer 110, a through hole 120, a metal layer 130, a conductive layer 140, and an adhesive layer 170.

The glass layer 110 serves as a core layer of the substrate 100. For the glass layer 110, various glass materials such as alkali-free glass, soda glass, and quartz glass may be used. For example, the glass layer 110 having a thickness of about 10 μm to 1000 μm is used. A wiring layer 131 of a predetermined pattern is formed over one surface 110a of the glass layer 110 by using a conductive material such as Cu. The wiring layer 131 that is continuous from the metal layer 130 provided in a part (portion 121) of the through hole 120 as will be described later is illustrated as an example.

As Illustrated in FIG. 5, the through hole 120 is provided so as to penetrate between the surface 110a and a surface 110b in the glass layer 110. For example, a through hole 120 of a tsuzumi shape in which a middle portion between the surface 110a and the surface 110b of the glass layer 110 is constricted is provided. The through hole 120 may have a cylindrical shape penetrating through the glass layer 110, a tapered shape whose inner diameter becomes larger or smaller from the surface 110a toward the surface 110b, or a drum shape in which the middle portion between the surfaces 110a and 110b is swollen, or the like. Although the illustration is omitted herein, a planar shape of an opening (an opening in the surface 110a or the surface 110b or an opening in a plane therebetween) of the through hole 120 may be various planar shapes in addition to a circular shape. For example, the through hole 120 having an inner diameter of about 10 μm to 100 μm is provided in the glass layer 110. The through hole 120 is formed by, for example, laser processing, sand blasting, electric discharge machining, etching with a chemical solution, or the like, or a combination of these.

As illustrated in FIG. 5, the metal layer 130 is provided in the through hole 120 of the glass layer 110. The metal layer 130 is provided in at least the portion 121 of the through hole 120 extending from the surface 110a and not reaching the surface 110b in the glass layer 110. As an example, a case where the metal layer 130 provided in the through hole 120 and the wiring layer 131 provided over the surface 110a of the glass layer 110 are coupled to each other is illustrated. The metal layer 130 functions as a part of a via (TGV) 150 that electrically couples the surface 110a to the surface 110b (achieves conduction between the surface 110a and the surface 110b) in the glass layer 110. The metal layer 130 is provided, for example, in the form of a conformal via over an inner wall 120a of the portion 121 of the through hole 120. In this case, as illustrated in FIG. 5, the substrate 100 may have a structure in which a space 160 formed inside the metal layer 130 is left as a cavity, or may have a structure in which, although the illustration is omitted herein, a filling material such as resin is injected into the space 160. Various metal materials may be used for the metal layer 130. For example, Cu or a material containing Cu is used for the metal layer 130. The metal layer 130 is formed by, for example, a plating method.

As Illustrated in FIG. 5, the conductive layer 140 is provided in the through hole 120 of the glass layer 110. The conductive layer 140 is provided at least in a portion 122 of the through hole 120 extending from the surface 110b and not reaching the surface 110a in the glass layer 110. The conductive layer 140 is provided so as to partially protrude from the through hole 120, that is, is provided such that an upper end 140b of the conductive layer 140 is positioned above the surface 110b of the glass layer 110. The conductive layer 140 functions as a part of the via 150 (TGV) that electrically couples the surface 110a to the surface 110b in the glass layer 110.

As illustrated in FIG. 6A, the conductive layer 140 contains a resin 141 and a conductive filler 142 mixed with the resin 141. The conductive layer 140 is formed by, for example, supplying a conductive paste (resin composition) containing the resin 141 in an uncured state and the conductive filler 142 into the through hole 120 provided with the metal layer 130 by using a method such as printing, application, or dripping, and curing the resin 141. The conductive layer 140 contains, for example, as illustrated in FIG. 6A, a conductive filler 142 having a particle size larger than an opening 161 (minimum value) of the space 160 surrounded by the metal layer 130. When the conductive filler 142 of such a particle size is contained, the conductive layer 140 hardly passes through the opening 161 to the space 160, and is blocked in the vicinity of an end portion of the metal layer 130.

Various kinds of resin materials may be used as the resin 141 of the conductive layer 140. For example, a resin material such as an epoxy resin or a polyimide resin is used as the resin 141. For example, a resin material such as a thermosetting resin, a thermoplastic resin, or a photocurable resin is used as the resin 141. The resin 141 may contain various components (additives) such as a solvent, a curing agent, a polymerization initiator, and the like.

Various conductive materials may be used for the conductive filler 142 of the conductive layer 140. For example, various metal materials may be used for the conductive filler 142. Examples of the metal materials used for the conductive filler 142 include tin (Sn) and solder containing Sn. In addition to these, for example, one kind of or two or more kinds of metal materials selected from Sn, Cu, silver (Ag), gold (Au), aluminum (Al), nickel (NI), platinum (Pt), palladium (Pd), and tungsten (W) may be used for the conductive filler 142. For the conductive filler 142, for example, particles 142a formed from various conductive materials may be used as illustrated in FIG. 6B. For example, as illustrated in FIG. 6C, particles 142b obtained by coating the surface of core particles 142ba with a coating layer 142bb of various conductive materials may be used for the conductive filler 142 as illustrated in FIG. 6C. In this case, a conductive material or an insulating material may be used for the core particles 142ba. The group of particles 142a and the group of particles 142b used for the conductive filler 142 may each have a certain particle size distribution.

The conductive layer 140 containing the resin 141 and the conductive filler 142 has a higher thermal expansion coefficient than the glass layer 110 and the metal layer 130. Further, the conductive layer 140 having a higher thermal expansion coefficient than the adhesive layer 170 is used. In the conductive layer 140, a material of the resin 141, and a material and content of the conductive filler 142 are adjusted such that the conductive layer 140 has a higher thermal expansion coefficient than the glass layer 110, the metal layer 130, and the adhesive layer 170. For example, the thermal expansion coefficient of the conductive layer 140 is adjusted in a range of 16 ppm/° C. to 50 ppm/° C. and more preferably within a range of 30 ppm/° C. to 45 ppm/° C.

The conductive layer 140 has a lower elastic modulus than the glass layer 110 and the metal layer 130. In the conductive layer 140, a material of the resin 141, and a material and content of the conductive filler 142 are adjusted such that the conductive layer 140 has a lower elastic modulus than the glass layer 110 and the metal layer 130. For example, the elastic modulus of the conductive layer 140 is adjusted to be 100 GPa or less, preferably 50 GPa or less, and more preferably in a range of 1 GPa to 10 GPa. A material having a higher elastic modulus than the glass layer 110 and the metal layer 130 as a physical value may be used for the conductive filler 142 contained in the conductive layer 140.

As Illustrated in FIG. 5, the adhesive layer 170 is provided over the surface 110b of the glass layer 110. The conductive layer 140 is provided so as to penetrate through the adhesive layer 170 and such that the upper end 140b thereof is exposed from the adhesive layer 170. The adhesive layer 170 is a layer used for bonding the substrate 100 to another substrate as will be described later. For the adhesive layer 170, various adhesive materials having adhesiveness may be used. For example, a resin material such as an epoxy resin or a polyimide resin is used for the adhesive layer 170. For example, a resin material such as a thermosetting resin, a thermoplastic resin, or a photocurable resin is used for the adhesive layer 170. The resin material of the adhesive layer 170 may contain various components (additives) such as a solvent, a curing agent, a polymerization initiator, and the like.

The adhesive layer 170 may further contain an insulating filler. For example, a resin composition containing a resin 171a and an insulating filler 172a such as glass particles or glass fibers mixed with the resin 171a as illustrated in FIG. 7A is used for the adhesive layer 170. Alternatively, a resin composition containing a resin 171b and an insulating filler 172b such as glass cloth mixed with the resin 171b as illustrated in FIG. 7B may be used for the adhesive layer 170.

As described above, in the conductive layer 140, a material of the resin 141, and a material and content of the conductive filler 142 are adjusted such that the conductive layer 140 has a higher thermal expansion coefficient than this adhesive layer 170. Alternatively, the material and composition of the adhesive layer 170 are adjusted such that the thermal expansion coefficient thereof is lower than that of the conductive layer 140 having a higher thermal expansion coefficient and lower elastic modulus than the glass layer 110 and the metal layer 130. In the example of FIG. 7A, the material of the resin 171a and the material and content of the insulating filler 172a are adjusted such that the thermal expansion coefficient of the adhesive layer 170 is lower than that of the conductive layer 140. In the example of FIG. 7B, the material of the resin 171b and the material and content of the insulating filler 172b are adjusted such that the thermal expansion coefficient of the adhesive layer 170 is lower than that of the conductive layer 140. For example, the thermal expansion coefficient of the adhesive layer 170 is adjusted to a value lower than that of the conductive layer 140 in the range of 10 ppm/° C. to 30 ppm/° C.

Next, a method of forming the substrate 100 having the above-described structure will be described.

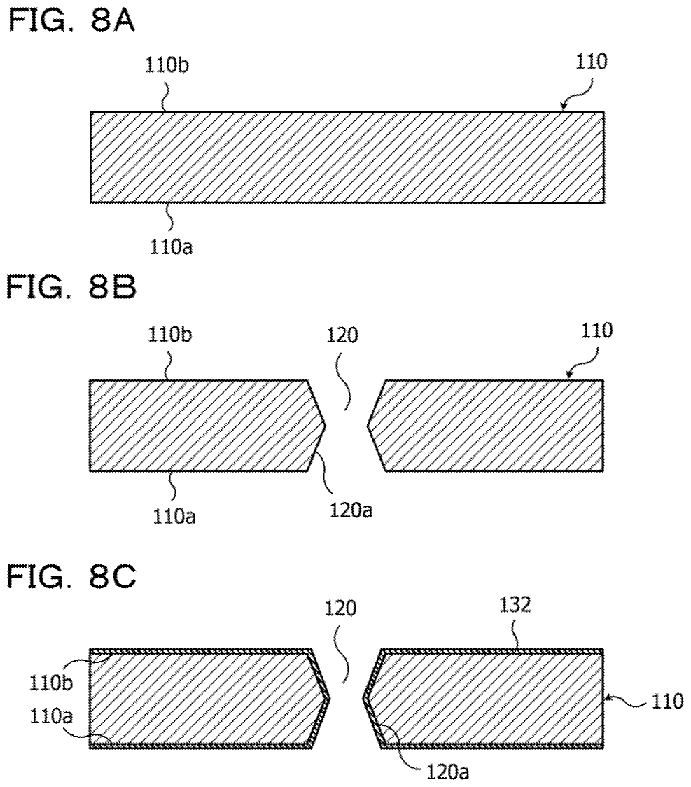

FIGS. 8A to 10C are diagrams for describing an example of a method of forming the substrate according to the second embodiment. FIGS. 8A to 8C, FIGS. 9A to 9C, and FIGS. 10A to 10C each schematically illustrate a sectional view of a principal part in an example of each step of formation of the substrate.

In the formation of the substrate 100, first, the glass layer 110 serving as a core layer as illustrated in FIG. 8A is prepared. For example, the glass layer 110 having a thickness of 100 μm is prepared.

Then, the through hole 120 having a predetermined opening size and penetrating between the surface 110a and the surface 110b as illustrated in FIG. 8B is formed in the prepared glass layer 110. For example, the through hole 120 whose opening size in the surfaces 110a and 110b is a diameter of 20 μm is formed. The through hole 120 is formed by, for example, a process using a picosecond laser and hydrofluoric acid etching. Alternatively, the through hole 120 may be formed by carbon dioxide (CO₂) laser processing, ultraviolet laser processing, sand blasting, electric discharge machining, or the like. The formation (processing) of the through hole 120 may be performed from both sides of the surface 110a and the surface 110b of the glass layer 110, or may be performed only from one side of the glass layer 110.

After forming the through hole 120, a seed layer 132 is formed over the surface of the glass layer 110 having the through hole 120 formed therein, that is, over the surface 110a and the surface 110b of the glass layer 110 and over the inner wall 120a of the through hole 120 as illustrated in FIG. 8C. For example, the seed layer 132 is formed, by a sputtering method, over the surface of the glass layer 110 in which the through hole 120 is formed. The seed layer 132 may be formed by an electroless plating method over the surface of the glass layer 110 in which the through hole 120 is formed. Various conductive materials, for example, metal materials such as Cu, chromium (Cr), titanium (Ti), and the like may be used for the seed layer 132.

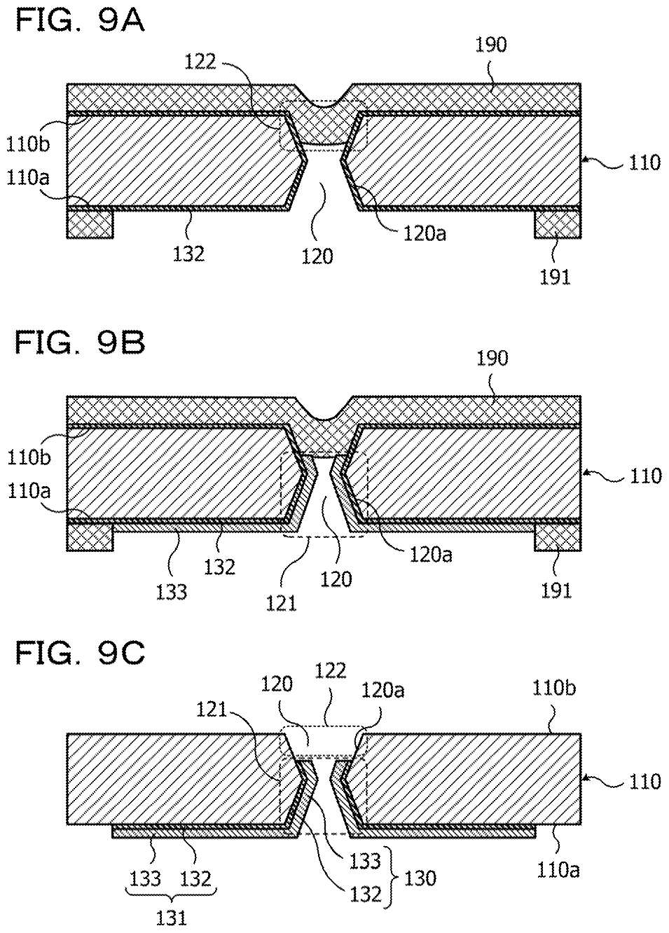

After the seed layer 132 is formed, as illustrated in FIG. 9A, a dry film resist 190 is formed over the surface 110b of the glass layer 110 over which the seed layer 132 is formed (surface 110b on the side where the conductive layer 140 is formed) such that the dry film resist 190 partially goes into the through hole 120. The dry film resist 190 is laminated over the surface 110b of the glass layer 110, and a laminating temperature thereof is set to a melting temperature of the dry film resist 190 or a temperature close to the melting temperature, so that a part of the dry film resist 190 which has been melted or softened goes into the through hole 120. Thus, the dry film resist 190 is formed in a state as illustrated in FIG. 9A in which the dry film resist 190 covers the surface 110b of the glass layer 110 and is partially in the through hole 120. A part of the inside of the through hole 120 covered with the dry film resist 190 that has entered the through hole 120 serves as the portion 122 in which the metal layer 130 described above is not formed and the conductive layer 140 described above is formed.

As illustrated in FIG. 9A, a dry film resist 191 is formed over the surface 110a of the glass layer 110 over which the seed layer 132 is formed (surface 110a on the side where the metal layer 130 is formed), in a region excluding a region in which the metal layer 130 and the wiring layer 131 are to be formed. At this time, first, the dry film resist 191 is laminated over the surface 110a of the glass layer 110. Then, the dry film resist 191 is patterned by exposure and development to form the dry film resist 191 in a state illustrated in FIG. 9A in which the dry film resist 191 covers the region over the surface 110a excluding the region where the metal layer 130 and the wiring layer 131 are to be formed.

After the dry film resist 190 and 191 are formed, as illustrated in FIG. 9B, a plating layer 133 is formed by an electroplating method using the dry film resists 190 and 191 as masks and the seed layer 132 as a feeding layer. A part of the through hole 120 of the glass layer 110 is covered by the dry film resist 190 that has entered the through hole 120, and the plating layer 133 is formed in the portion 121 of the through hole 120 extending from the surface 110a, not reaching the surface 110b, and not covered by the dry film resist 190. The plating layer 133 is formed over the surface 110a of the glass layer 110 in a region not covered by the dry film resist 191. As an example, the plating layer 133 continuing from the inside of the through hole 120 to the surface 110a is illustrated.

After the formation of the plating layer 133, as illustrated in FIG. 9C, the dry film resists 190 and 191 are removed by peeling or the like, and the seed layer 132 exposed after removal of the dry film resists 190 and 191 is removed by etching. Consequently, a state illustrated in FIG. 9C is obtained in which the seed layer 132 and the plating layer 133 are formed only in the portion 121 which is a part of the through hole 120, and the seed layer 132 and the plating layer 133 are not formed in the portion 122 which is the other part of the through hole 120. In the following, the seed layer 132 in the through hole 120 and the plating layer 133 thereover serve as the metal layer 130, and the seed layer 132 over the surface 110a and the plating layer 133 thereover serve as the wiring layer 131.

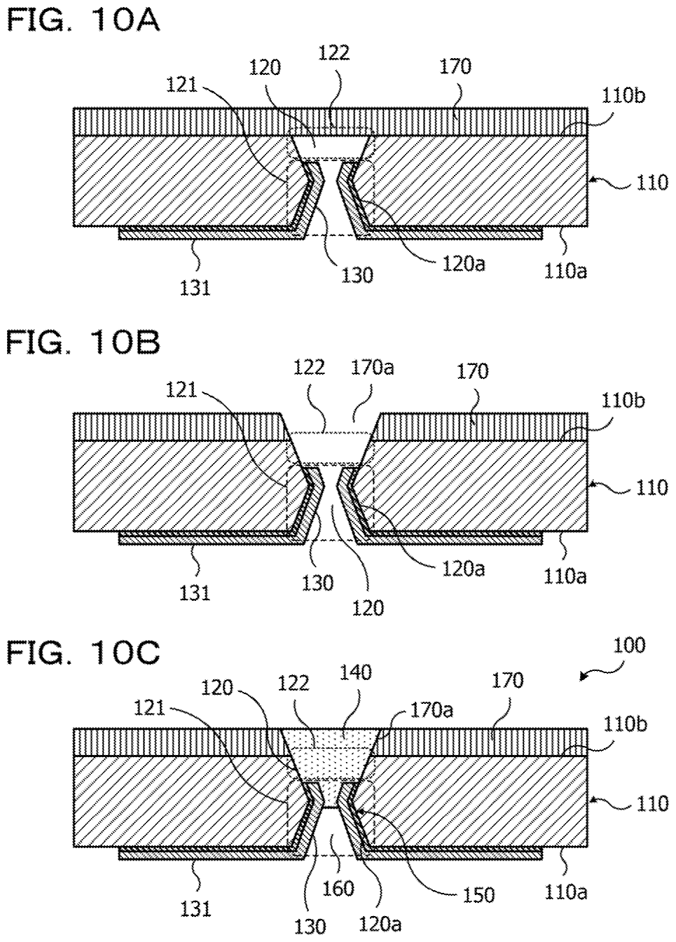

After the formation of the metal layer 130 and the wiring layer 131, the adhesive layer 170 is formed over the surface 110b of the glass layer 110 as illustrated in FIG. 10A. For example, a dry film formed from a resin material having a predetermined composition to be the adhesive layer 170 or a resin composition containing a predetermined insulating filler (such as the insulating filler 172a illustrated in FIG. 7A or the insulating filler 172b illustrated in FIG. 7B) is laminated over the surface 110b to form the adhesive layer 170.

After the formation of the adhesive layer 170, as illustrated in FIG. 10B, a perforation process is performed on a portion of the adhesive layer 170 corresponding to the through hole 120 of the glass layer 110. For example, by laser processing, a hole 170a communicating with the through hole 120 as illustrated in FIG. 10B is formed in a portion of the adhesive layer 170 corresponding to the through hole 120.

After the formation of the hole 170a of the adhesive layer 170, as illustrated in FIG. 10C, the conductive layer 140 is formed in the hole 170a of the adhesive layer 170 and in the through hole 120 communicating therewith. For example, a conductive paste (resin composition containing the resin 141 in an uncured state and the conductive filler 142 as illustrated in FIG. 6A) containing an uncured resin and a conductive filler is printed over the adhesive layer 170 in which the hole 170a is formed. In this manner, the conductive paste is injected into the hole 170a and in the through hole 120, thereby forming the conductive layer 140. The conductive layer 140 is injected into at least the portion 122 of the through hole 120 extending from the surface 110b and not reaching the surface 110a, and is coupled to the metal layer 130. The conductive layer 140 may partially go into the space 160 surrounded by the metal layer 130. The part of the conductive layer 140 that goes into the space 160 may include both the resin 141 and the conductive filler 142 or only the resin 141, depending on the size and particle size distribution of the conductive filler 142 contained in the conductive layer 140.

By the method described above, the substrate 100 as illustrated in FIGS. 10C and 5 is formed.

The adhesive layer 170 and the conductive layer 140 may be completely cured, semi-cured, or uncured at the time of forming the substrate 100, as long as the substrate 100 is capable of being melted or softened at the time of being laminated with another substrate and cured thereafter as will be described later.

Next, a multilayer substrate including the substrate 100 having the above-described structure will be described.

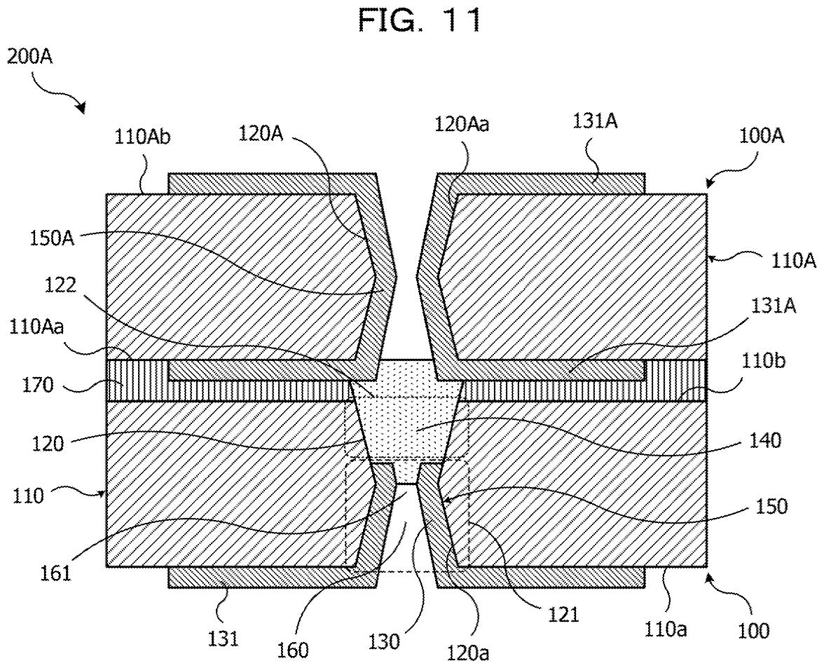

FIGS. 11 to 13 are diagrams for describing an example of a multilayer substrate according to the second embodiment. FIGS. 11 to 13 each schematically illustrate a sectional view of a principal part of an example of a multilayer substrate.

A multilayer substrate 200A illustrated in FIG. 11 has a structure in which another substrate 100A is laminated over the substrate 100 (above the surface 110b side of the glass layer 110) with the adhesive layer 170 therebetween. The substrate 100A to be laminated includes a glass layer 110A serving as a core layer, a through hole 120A provided in the glass layer 110A, and a conformal via 150A provided over an inner wall 120Aa of the through hole 120A. The substrate 100A to be laminated further includes a wiring layer 131A provided over a surface 110Aa and a surface 110Ab of the glass layer 110A continuously from the conformal via 150A in the through hole 120A.

The multilayer substrate 200A is formed by a batch lamination process in which the substrate 100 and the substrate 100A described above are laminated and hot-pressed under predetermined conditions of temperature and pressure, for example, a temperature of 200° C. and a pressure of 30 kg/cm². By the hot pressing, the conductive layer 140 of the via 150 of the substrate 100 and the conformal via 150A of the substrate 100A or the wiring layer 131A (conductive coupling portion) coupled thereto are joined to each other, and thus the via 150 is electrically coupled to the conformal via 150A.

By the heating in the hot pressing, the adhesive layer 170 and the conductive layer 140 of the substrate 100 are melted or softened, and the wiring layer 131A provided over the surface 110Aa of the substrate 100A opposed to the adhesive layer 170 is embedded in the adhesive layer 170. At the same time, the conformal via 150A or the wiring layer 131A is coupled to the conductive layer 140.

In the substrate 100, a part (portion 122) inside the through hole 120 of the substrate 100 is not the metal layer 130 having a relatively high elastic modulus but the conductive layer 140 having a relatively low elastic modulus. Therefore, the stress generated in the glass layer 110 is relieved even when heat is applied to the substrate 100 and the conductive layer 140 thermally expands, such as when the substrate 100 is hot-pressed, when a semiconductor chip is mounted over the substrate 100 thereafter, when a test is performed after the mounting, or when the substrate 100 is used.

Further, in the substrate 100, the conductive layer 140 having a higher thermal expansion coefficient than the glass layer 110, the metal layer 130, and the adhesive layer 170 is used. Therefore, the conductive layer 140 relatively more greatly thermally expands than the surroundings thereof (the glass layer 110, the metal layer 130, and the adhesive layer 170) when heat is applied to the substrate 100, such as when the substrate 100 is hot-pressed, when a semiconductor chip is mounted over the substrate 100 thereafter, when a test is performed after the mounting, or when the substrate 100 is used. Due to this thermal expansion of the conductive layer 140, the conductive layer 140 is strongly pressed against the metal layer 130 in the through hole 120, so that an increase in the coupling resistance therebetween and occurrence of coupling failure therebetween may be suppressed.

The pressing force caused by such thermal expansion of the conductive layer 140 also acts on the wiring layer 131A of the substrate 100A to be laminated in a similar manner as well as the metal layer 130 in the through hole 120 of the substrate 100. As a result of this, an increase in the coupling resistance between and occurrence of coupling failure between the conductive layer 140 and the wiring layer 131A may be suppressed.

When the conductive layer 140 contains the conductive filler 142 larger than the opening 161 of the space 160 surrounded by the metal layer 130, the conductive layer 140 hardly passes through the opening 161 to the space 160, and is blocked in the vicinity of an end portion of the metal layer 130. Thus, a strong force of pressing the conductive layer 140, which thermally expands when heat is applied to the substrate 100, against the end portion of the metal layer 130 in the through hole 120 may be obtained, and an increase in the coupling resistance between these and occurrence of coupling failure may be effectively suppressed.

In the through hole 120, the via 150 for which an increase in the resistance is suppressed is formed in the through hole 120 by providing the metal layer 130 formed from a metal material such as Cu together with the conductive layer 140 containing the resin 141 and the conductive filler 142. For example, in the through hole 120, the metal layer 130 is provided in the portion 121 at a depth equal to or more than a half of the depth of the through hole 120 from the surface 110b to the surface 110a in the glass layer 110 and equal to or less than a depth obtained by subtracting the thickness of the wiring layers 131 and 131A provided over the glass layer 110 from the depth of the through hole 120. Thus, stress generated in the glass layer 110 may be relieved by the conductive layer 140, and the occurrence of the cracks therein may be suppressed, and further, by including not only the conductive layer 140 but also a certain amount of the metal layer 130, an increase in the resistance as the via 150 may be suppressed.

By using the substrate 100 having the above-described structure, the multilayer substrate 200A having high conduction reliability in which an increase in the coupling resistance and occurrence of coupling failure in or via the via 150 are suppressed may be realized.

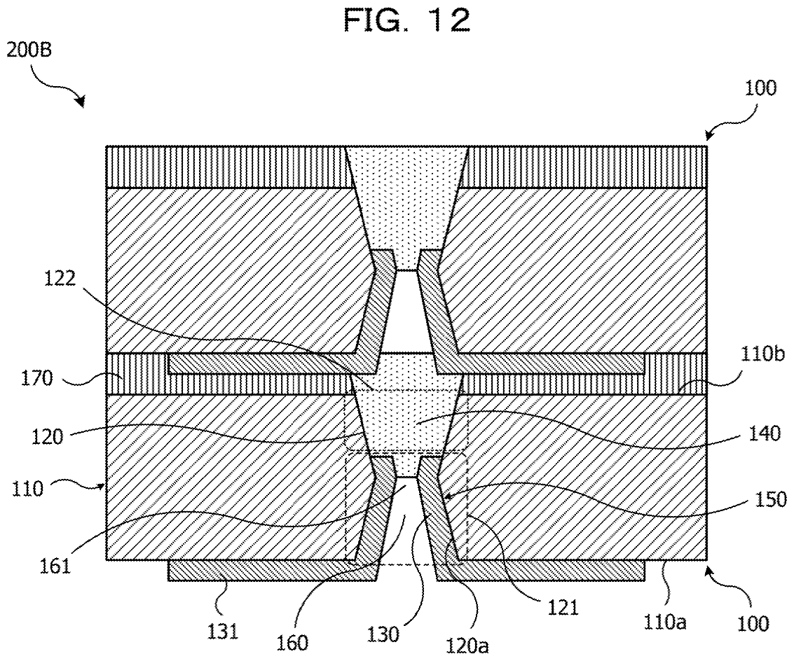

A multilayer substrate 200B illustrated in FIG. 12 has a structure in which two substrates 100 described above are laminated with the adhesive layer 170 therebetween. The multilayer substrate 2008 is formed by a batch lamination process in which the two substrates 100 are laminated and hot-pressed under predetermined conditions of temperature and pressure, for example, a temperature of 200° C. and a pressure of 30 kg/cm². By the hot pressing, the conductive layer 140 of the via 150 of one of the substrates 100 and the metal layer 130 of the via 150 of the other of the substrates 100 or the wiring layer 131 (conductive coupling portion) coupled thereto are joined to each other, and thus the vias 150 are electrically coupled to each other.

Also in the multilayer substrate 200B, the stress generated in the glass layer 110 when heat is applied thereto may be relieved as a result of a part (portion 122) of the through hole 120 being not the metal layer 130 having a relatively high elastic modulus but the conductive layer 140 having a relatively low elastic modulus.

Further, when heat is applied, the conductive layer 140 having a higher thermal expansion coefficient than the glass layer 110, the metal layer 130, and the adhesive layer 170 is thermally expanded relatively greatly and is strongly pressed against the metal layer 130 in the through hole 120, thereby suppressing an increase in the coupling resistance therebetween and occurrence of coupling failure therebetween. The pressing force caused by the thermal expansion of the conductive layer 140 acts similarly on the wiring layer 131 of the other substrate 100 to be laminated in addition to on the metal layer 130 in the through hole 120 of the one substrate 100, so that an increase in the coupling resistance between and occurrence of coupling failure between the conductive layer 140 and the wiring layer 131 may be suppressed.

When the conductive layer 140 contains the conductive filler 142 larger than the opening 161 surrounded by the metal layer 130, the conductive layer 140 is blocked in the vicinity of an end portion of the metal layer 130, and a strong force of pressing the end portion of the metal layer 130 in the through hole 120 is obtained from the conductive layer 140 that thermally expands. As a result of this, an increase in the coupling resistance between and occurrence of coupling failure between the conductive layer 140 and the metal layer 130 may be effectively suppressed.

In the through hole 120, the metal layer 130 formed from a metal material such as Cu is provided together with the conductive layer 140 containing the resin 141 and the conductive filler 142. The stress generated in the glass layer 110 may be relieved and the occurrence of the cracks therein may be suppressed by the conductive layer 140, and further, by including not only the conductive layer 140 but also a certain amount of the metal layer 130, an increase in the resistance as the via 150 may be suppressed.

By using the substrate 100 having the above-described structure, the multilayer substrate 200B having high conduction reliability in which an increase in the coupling resistance and occurrence of coupling failure in the via 150 or via the via 150 are suppressed may be realized.

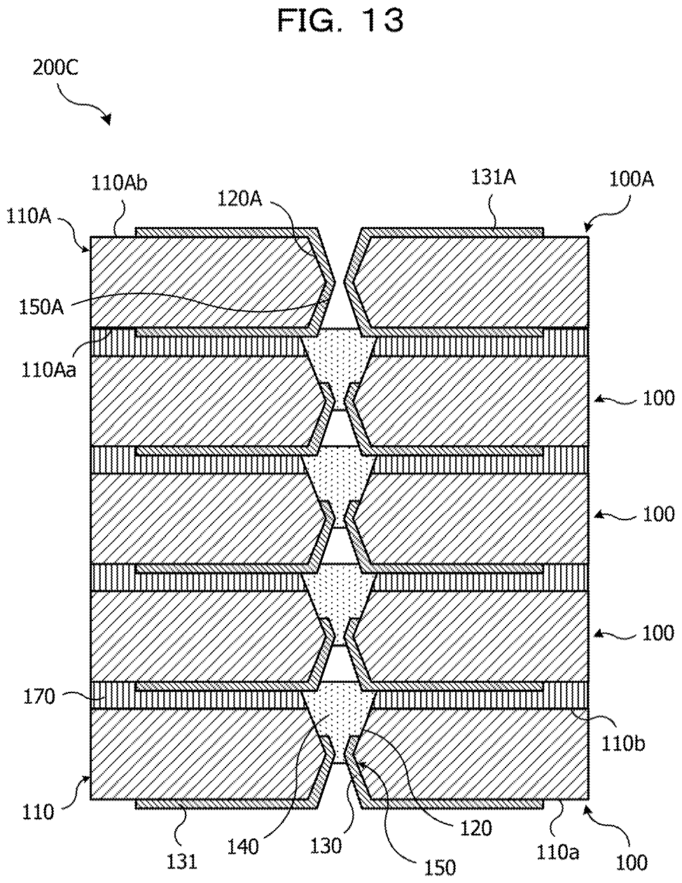

A multilayer substrate 200C illustrated in FIG. 13 has a structure in which four substrates 100 and further one substrate 100A described above (FIG. 11) are laminated with adhesive layers 170 therebetween. The multilayer substrate 200C is formed by a batch lamination process in which the four substrates 100 and the one substrate 100A are laminated in an order illustrated in FIG. 13 and hot-pressed under predetermined conditions of temperature and pressure, for example, a temperature of 200° C. and a pressure of 30 kg/cm.

The number of laminated substrates for forming the multilayer structure is not limited to two like the multilayer substrates 200A and 200B described above, and may be five like this multilayer substrate 200C. Of course, the number of laminated substrates is not limited to five, and may be three, four, or six or more.

In the multilayer substrate 200C, the same effects and advantages as those described for the multilayer substrates 200A and 200B described above may be obtained for each of the substrates 100, between the laminated substrates 100, and between the laminated substrates 100 and 100A. By using the substrate 100 having the above-described structure, the multilayer substrate 200C having high conduction reliability in which an increase in the coupling resistance and occurrence of coupling failure in the via 150 or via the via 150 are suppressed may be realized.

Next, analysis results of the stress generated in the substrate 100 having the above-described structure will be described.

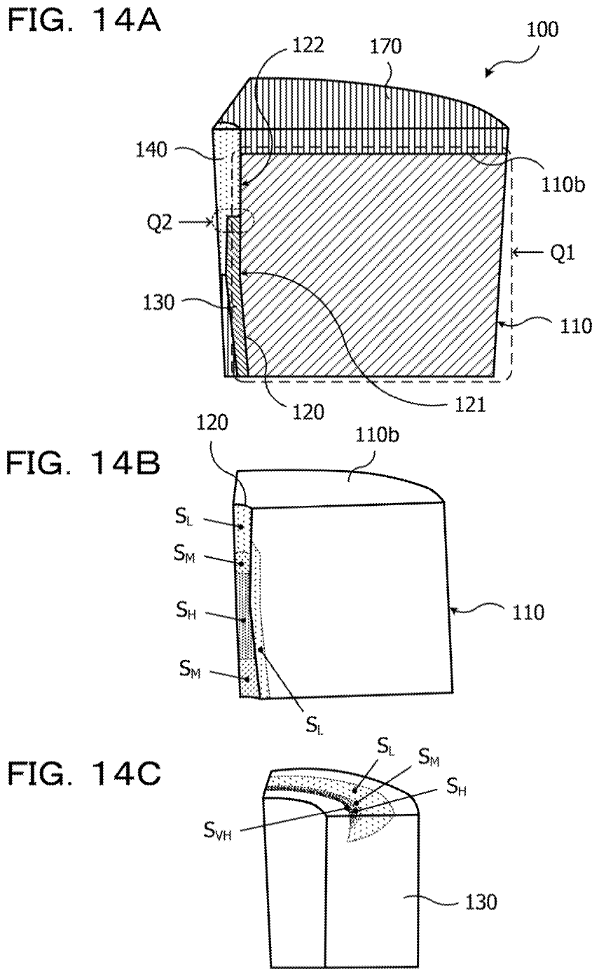

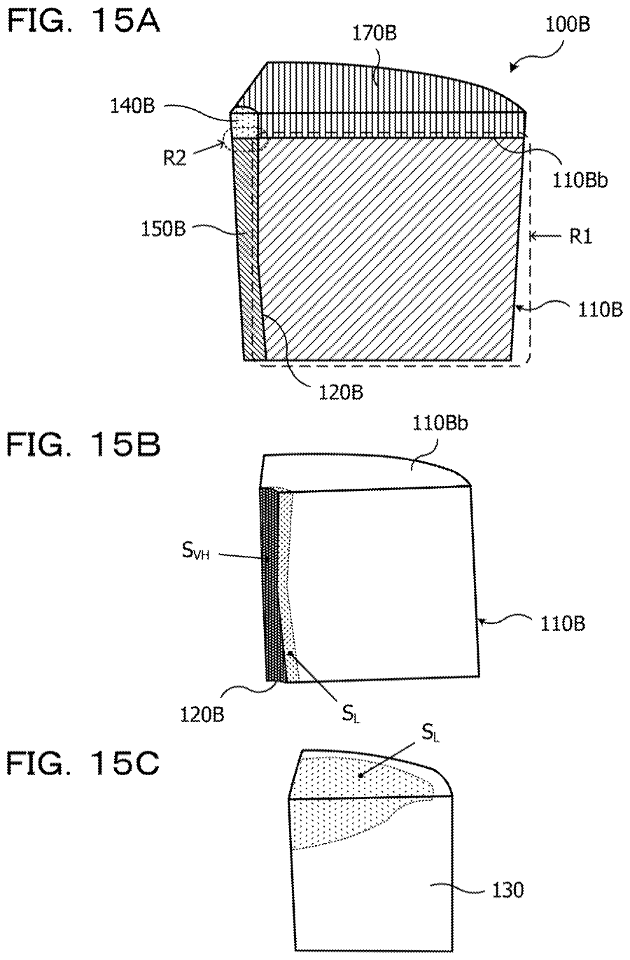

FIGS. 14A to 14C are diagrams for describing an example of stress analysis results of the substrate according to the second embodiment. FIGS. 15A to 15C are diagrams for describing an example of stress analysis results of a substrate of a different structure.

FIGS. 14A to 14C schematically illustrate an example of the substrate 100 described above and stress analysis results obtained therefor, for the sake of convenience. FIG. 14A schematically illustrates a perspective view of a principal part of the glass layer 110, the through hole 120, the metal layer 130, the conductive layer 140, and the adhesive layer 170 of the substrate 100. FIG. 14B schematically illustrates an example of analysis results of stress generated in the glass layer 110 (portion Q1 of FIG. 14A) when heat is applied to the substrate 100. FIG. 14C schematically illustrates an example of analysis results of stress generated in a coupling interface (portion Q2 of FIG. 14A) between the metal layer 130 and the conductive layer 140 when heat is applied to the substrate 100.

For comparison, FIGS. 15A to 15C schematically illustrate an example of a substrate 100B (corresponding to the substrate 1B illustrated in FIG. 3) provided with a filled via 150B in a through hole 120B of a glass layer 110B and stress analysis results obtained therefor, for the sake of convenience. FIG. 15A schematically illustrates a perspective view of a principal part of the glass layer 110B, the through hole 120B, the filled via 1508, the conductive layer 140B over the filled via 150B, and the adhesive layer 170B over the surface 110Bb of the glass layer 110B of the substrate 100B. FIG. 15B schematically illustrates an example of analysis results of stress generated in the glass layer 110B (portion R1 of FIG. 15A) when heat is applied to the substrate 100B. FIG. 15C schematically illustrates an example of analysis results of stress generated in a coupling interface (portion R2 of FIG. 15A) between the filled via 150B and the conductive layer 1408 when heat is applied to the substrate 100B.

In FIGS. 14B and 14C and FIGS. 158 and 15C, for the sake of convenience, stress is represented by 4 levels of “very high stress Si,”, “high stress S”, “moderate stress S_{M}”, and “low stress S_{L}”. The metal layer 130 and the filled via 150B are formed from Cu, the thermal expansion coefficient of the conductive layer 140 is set to be higher than the thermal expansion coefficient of the adhesive layer 170 in the substrate 100, and the thermal expansion coefficient of the conductive layer 140B is set to be lower than the thermal expansion coefficient of the adhesive layer 170B in the substrate 100B.

First, the substrate 100B in which the filled via 1508 is provided in the through hole 120B of the glass layer 110B as illustrated in FIG. 15A will be described.

In the substrate 100B, when heat is applied, a very high stress S_{VH} is concentratedly generated around the entirety of the through hole 120B in the glass layer 110B as illustrated in FIG. 158. Since the filled via 1508 has a higher thermal expansion coefficient and a higher elastic modulus than the glass layer 1108, the very high stress S_{VH} is generated around the through hole 120B of the glass layer 1108 by the highly elastic filled via 150B that thermally expands when heat is applied thereto. In the substrate 100B, due to this very high stress S_{VH}, cracks are likely to be generated in the glass layer 110B, and snapping or the like caused by cracks is likely to occur.

In contrast, when heat is applied to the substrate 100B, a low stress S_{L} is generated at the coupling interface between the filled via 150B and the conductive layer 1408 as illustrated in FIG. 15C. This means that the force of pressing the conductive layer 140B against the filled via 150B is small. One reason for this is that, when heat is applied, the conductive layer 140B having a relatively low thermal expansion coefficient is pulled by the adhesive layer 170B having a relatively high thermal expansion coefficient, and the force of pressing the conductive layer 140B against the filled via 150B is reduced. When the force of pressing the conductive layer 140B against the filled via 150B is reduced in this manner, there is a possibility that the coupling resistance between the conductive layer 140B and the filled via 150B is increased.

Next, the substrate 100 in which the metal layer 130 is provided in a part (portion 121) of the through hole 120 of the glass layer 110, and the conductive layer 140 is provided in the other part (portion 122) of the through hole 120 to form the via 150 as illustrated in FIG. 14A will be described.

When heat is applied to the substrate 100, as illustrated in FIG. 14B, in the glass layer 110, a high stress S_{H} and a moderate stress S_{M} lower than the high stress S_{H} are generated around the portion 121 of the through hole 120 where the metal layer 130. However, the stress S_{H} generated around the portion 121 of the through hole 120 in the glass layer 110 of the substrate 100 is lower than the stress S_{VH} generated around the entirety of the through hole 120B in the glass layer 110B of the substrate 100B. In the glass layer 110 of the substrate 100, a low stress Si is generated around the portion 122 of the through hole 120 where the conductive layer 140 is provided.

As described above, in the substrate 100, stress generated around the entirety of the through hole 120 in the glass layer 110 is relieved as compared with the case of the substrate 100B. One reason for this is that, as a result of the metal layer 130 having a higher thermal expansion coefficient and a higher elastic modulus than the glass layer 110 being formed as a conformal via and provided only in a part of the through hole 120, the influence of thermal expansion of the metal layer 130 on the glass layer 110 when heat is applied thereto is reduced. Another reason is that, as a result of the conductive layer 140 having a low elastic modulus being provided in the other part of the through hole 120 where the metal layer 130 is not provided, stress generated around the other part in the glass layer 110 when heat is applied thereto is relieved. In the substrate 100, stress generated in the glass layer 110 may be relieved in this manner, and thus generation of cracks in the glass layer 110 and occurrence of snapping or the like caused by the cracks may be suppressed.

In contrast, when heat is applied to the substrate 100, as illustrated in FIG. 14C, a high stress S_{H}, a moderate stress S_{M} smaller than the high stress S_{H}, and a low stress S_{L} smaller than the moderate stress SN are generated in the coupling interface between the metal layer 130 and the conductive layer 140. The occurrence of the high stress S_{H} and the moderate stress S_{M} in the coupling interface between the metal layer 130 and the conductive layer 140 means that the force of pressing the conductive layer 140 against the metal layer 130 has increased or the firmness of the contact between the conductive layer 140 and the metal layer 130 has increased. One reason for this is that, when heat is applied, the conductive layer 140 having a higher thermal expansion coefficient than the glass layer 110, the metal layer 130, and the adhesive layer 170 is thermally expanded relatively greatly and is strongly pressed against the metal layer 130 in the through hole 120. When the conductive filler 142 contained in the conductive layer 140 is adjusted so as to block the conductive layer 140 in the vicinity of an end portion of the metal layer 130 as described above, the conductive layer 140 is strongly pressed against the end portion of the metal layer 130. When heat is applied, in the substrate 100, a strong force of pressing the conductive layer 140 against the metal layer 130 acts, and thus an increase in the coupling resistance therebetween and occurrence of coupling failure therebetween may be effectively suppressed.

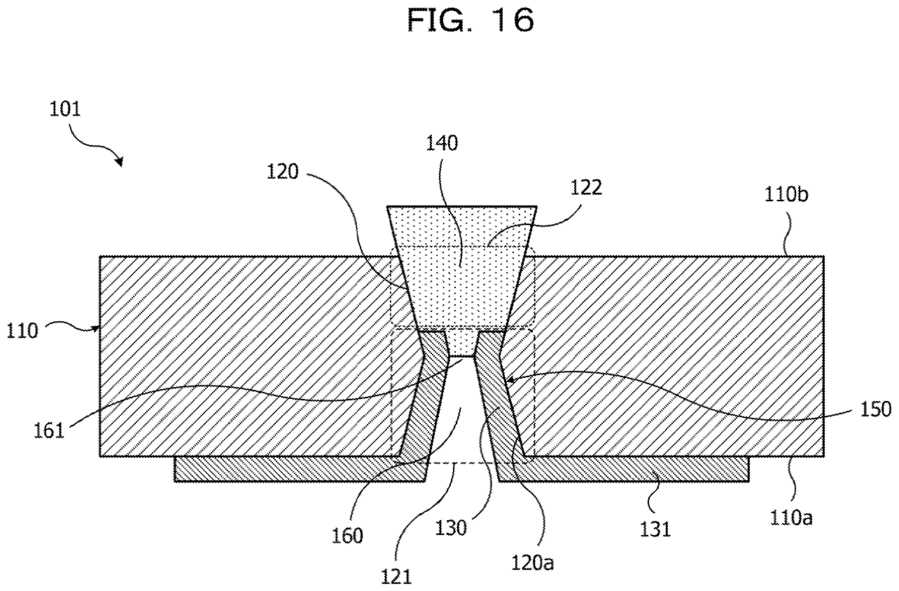

Next, modifications of the substrate 100 will be described with reference to FIGS. 16 to 20B.

FIG. 16 is a diagram for describing a first modification of the substrate according to the second embodiment FIG. 16 schematically illustrates a cross-sectional view of a principal part of an example of a substrate.

A substrate 101 illustrated in FIG. 16 is different from the substrate 100 described above in that the adhesive layer 170 is not provided in advance on the surface 110b side of the glass layer 110. As described above, the adhesive layer 170 does not have to be necessarily provided over the glass layer 110 in advance.

Such a substrate 101 is formed, for example, as follows. First, after the steps of FIG. 8A to and 9C, a dry film resist is formed over the surface 110b of the glass layer 110 in place of the adhesive layer 170 in accordance with the example of a step illustrated in FIG. 10A. Next, a hole communicating with the through hole 120 of the glass layer 110 is formed in the formed dry film resist in accordance with an example of a step illustrated in FIG. 10B. Then, a conductive paste to be the conductive layer 140 is printed over the dry film resist having the hole formed therein, in accordance with an example of a step illustrated in FIG. 10C. In the formation of the substrate 101, the dry film resist is removed by peeling or the like after the conductive paste is printed (after the conductive layer 140 is formed). As a result, the substrate 101 as illustrated in FIG. 16 is formed.

In the substrate 101, the conductive layer 140 having a lower elastic modulus than the metal layer 130 is provided in a part (portion 122) of the through hole 120, so that stress generated in the glass layer 110 may be relieved. Further, in the substrate 101, the conductive layer 140 having a higher thermal expansion coefficient than the glass layer 110 and the metal layer 130 is thermally expanded relatively greatly and is strongly pressed against the metal layer 130, and thus an increase in the coupling resistance between and occurrence of coupling failure between the conductive layer 140 and the metal layer 130 may be suppressed.

When the substrate 101 is laminated with another substrate, the adhesive layer 170 is interposed between the substrates. In the substrate 101, the adhesive layer 170 having such characteristics that the conductive layer 140 is sufficiently pressed against the metal layer 130 due to thermal expansion may be appropriately selected based on characteristics of the conductive layer 140 provided therein such as a thermal expansion coefficient, the hot pressing conditions for forming the multilayer structure, and the like. According to the substrate 101, the versatility thereof may be enhanced.

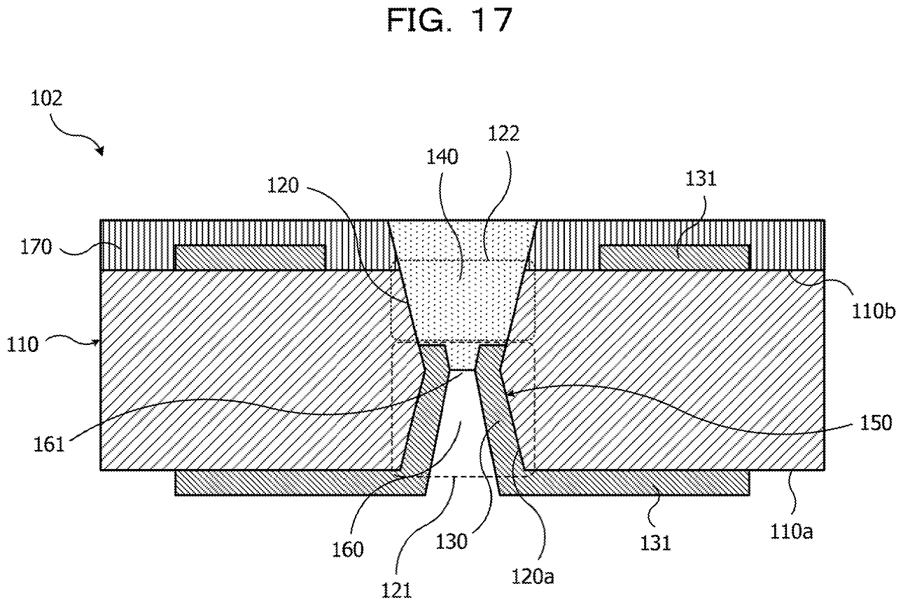

FIG. 17 is a diagram for describing a second modification of the substrate according to the second embodiment. FIG. 17 schematically illustrates a cross-sectional view of a principal part of an example of a substrate.

A substrate 102 illustrated in FIG. 17 has a structure of a so-called double-sided wiring board in which the wiring layer 131 is provided over not only the surface 110a but also the surface 110b in the glass layer 110.

Such a substrate 102 is formed, for example, as follows. First, after the steps of FIGS. 8A to 9A, patterning of the dry film resist 190 is performed, and an opening is formed in a region where the wiring layer 131 over the surface 110b is to be formed. Thereafter, each step is performed in accordance with the example of steps illustrated in FIGS. 9B to 10C to form the substrate 102 as illustrated in FIG. 17.

As in the substrate 102, the wiring layer 131 may be formed not only over the one surface 110a but also over the other surface 110b of the glass layer 110.

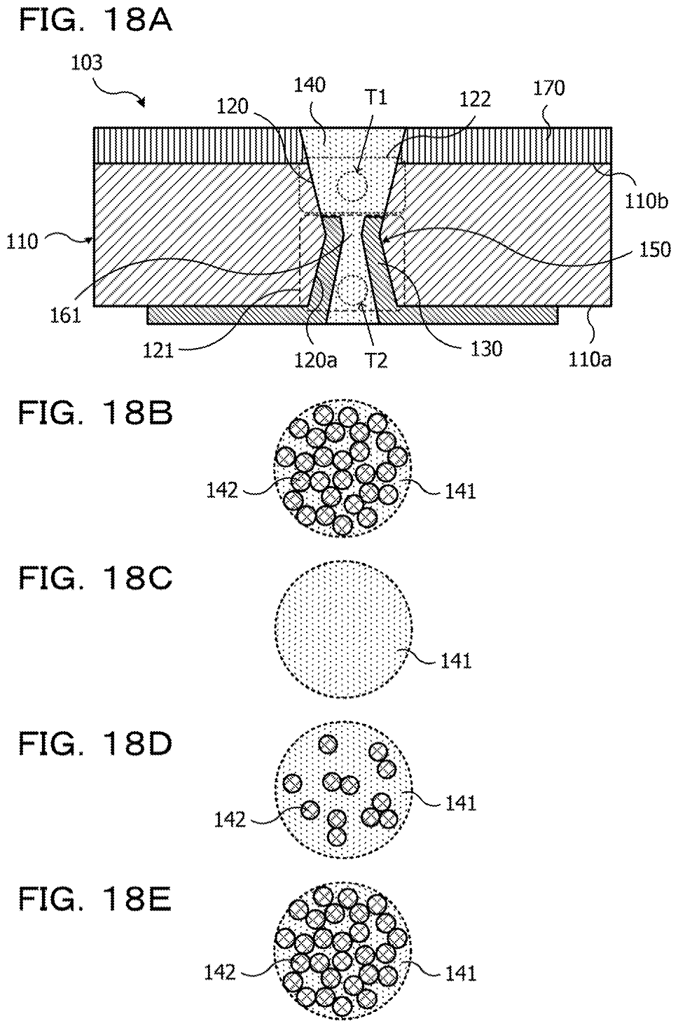

FIGS. 18A to 18E are diagrams for describing a third modification of the substrate according to the second embodiment FIG. 18A schematically illustrates a cross-sectional view of a principal part of an example of a substrate. FIG. 18B schematically illustrates an enlarged sectional view of an example of a portion T1 of FIG. 18A. FIGS. 18C to 18E each schematically illustrate an enlarged sectional view of an example of a portion T2 of FIG. 18A.

A substrate 103 illustrated in FIG. 18A has a structure in which the conductive layer 140 or the resin 141 thereof is injected into a space surrounded by the metal layer 130 provided over the inner wall 120a of the through hole 120 of the glass layer 110.

Such a substrate 103 is formed in accordance with the example of steps illustrated in FIGS. 8A to 10C. In the substrate 103, the conductive paste to be the conductive layer 140 is injected into the portion 122 of the through hole 120 of the glass layer 110 where the metal layer 130 is not provided, and is also injected into the portion 121 where the metal layer 130 is provided.

A case in which the conductive filler 142 contained in the conductive paste to be the conductive layer 140 together with the resin 141 is larger in size than the opening 161 surrounded by the metal layer 130 will be considered. In this case, the portion 122 of the through hole 120 is filled with the conductive layer 140 containing the resin 141 and a large number of particles of the conductive filler 142, for example, as illustrated in FIG. 18B. Since the conductive filler 142 does not pass through the opening 161, only the resin 141 passes through the opening 161, and the resin 141 that does not contain the conductive filler 142 is injected into the portion 121 of the through hole 120, for example, as illustrated in FIG. 18C. In the case of the distribution illustrated in FIG. 18B or 18C, when heat is applied to the substrate 103, coupling between the conductive filler 142 and the metal layer 130 and between the particles of the conductive filler 142 may be easily achieved in the portion 122 containing a large number of particles of the conductive filler 142. As a result of this, an increase in the coupling resistance between and occurrence of coupling failure between the conductive layer 140 and the metal layer 130 may be suppressed.

A case in which the conductive filler 142 contained in the conductive paste to be the conductive layer 140 together with the resin 141 partially includes particles smaller than the opening 161 surrounded by the metal layer 130 will be considered. In this case, the portion 122 of the through hole 120 is filled with the conductive layer 140 containing the resin 141 and a large number of particles of the conductive filler 142, for example, as illustrated in FIG. 18B. Since the particles smaller than the opening 161 in the conductive filler 142 pass through the opening 161, the resin 141 containing a smaller number of particles of the conductive filler 142 than in the portion 122 is injected into the portion 121 of the through hole 120, for example, as illustrated in FIG. 18D. Also in the case of the distribution illustrated in FIG. 18B or 18D, when heat is applied to the substrate 103, coupling between the conductive filler 142 and the metal layer 130 and between the particles of the conductive filler 142 may be achieved in the portion 122 containing a large number of particles of the conductive filler 142. As a result of this, an increase in the coupling resistance between and occurrence of coupling failure between the conductive layer 140 and the metal layer 130 may be suppressed.

A case in which the conductive filler 142 contained in the conductive paste to be the conductive layer 140 together with the resin 141 is smaller in size than the opening 161 surrounded by the metal layer 130 will be considered. In this case, the portion 122 of the through hole 120 is filled with the conductive layer 140 containing the resin 141 and a large number of particles of the conductive filler 142, for example, as illustrated in FIG. 18B. Since the conductive filler 142 pass through the opening 161, the conductive layer 140 containing the resin 141 and the large number of particles of the conductive filler 142 is also injected into the portion 121 of the through hole 120, for example, as illustrated in FIG. 18E. In the case of the distribution illustrated in FIG. 18B or 18E, the conductive filler 142 is contained in the entirety of the through hole 120, and coupling between the conductive filler 142 and the metal layer 130 and between the particles of the conductive filler 142 may be achieved. As a result of this, an increase in the coupling resistance between and occurrence of coupling failure between the conductive layer 140 and the metal layer 130 may be suppressed.

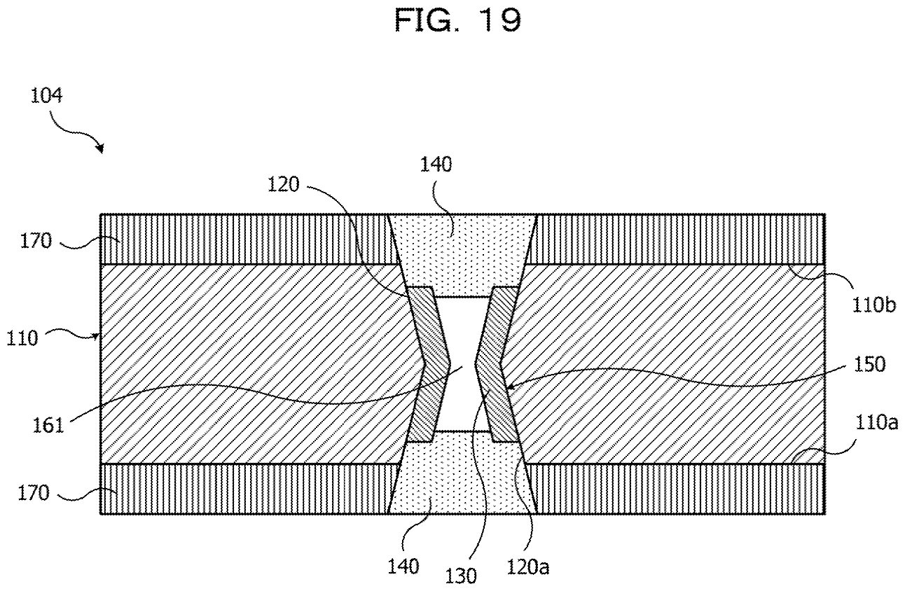

FIG. 19 is a diagram for describing a fourth modification of the substrate according to the second embodiment. FIG. 19 schematically illustrates a cross-sectional view of a principal part of an example of a substrate.

A substrate 104 illustrated in FIG. 19 has a structure in which the conductive layer 140 is provided not only on the surface 110b side but also on the surface 110a side of the glass layer 110, and the metal layer 130 is provided between the conductive layer 140 on the surface 110b side and the conductive layer 140 on the surface 110a side so as to be coupled to these conductive layers.

Such a substrate 104 is formed, for example, as follows. First, after the steps of FIGS. 8A to 9C, the metal layer 130 formed in the through hole 120 is partially protected by a resist or the like, and the metal layer 130 formed near the edge of the through hole 120 on the surface 110a side is removed. Thereafter, the conductive layer 140 is formed on the surface 110b side of the glass layer 110 by performing the steps of FIGS. 10A to 10C described above, and the conductive layer 140 is formed also on the surface 110a side of the glass layer 110 in accordance with the example of steps illustrated in FIGS. 10A to 10C described above. As a result, the substrate 104 as illustrated in FIG. 19 is formed.

In the substrate 104, the same actions and effects as those described above for the substrate 100 may be obtained on both the surface 110b side and the surface 110a side of the glass layer 110. That is, in the substrate 104, stress in the vicinity of edges of the through hole 120 both on the surface 110b side and the surface 110a side may be relieved, and generation of cracks in the glass layer 110, snapping caused by the cracks, and the like may be suppressed. Further, in the substrate 104, when heat is applied, both of the conductive layers 140 on the surface 110b side and the surface 110a side are pressed against the metal layer 130 due to thermal expansion thereof, so that an increase in the coupling resistance between and occurrence of coupling failure between the conductive layers 140 and the metal layer 130 may be suppressed.

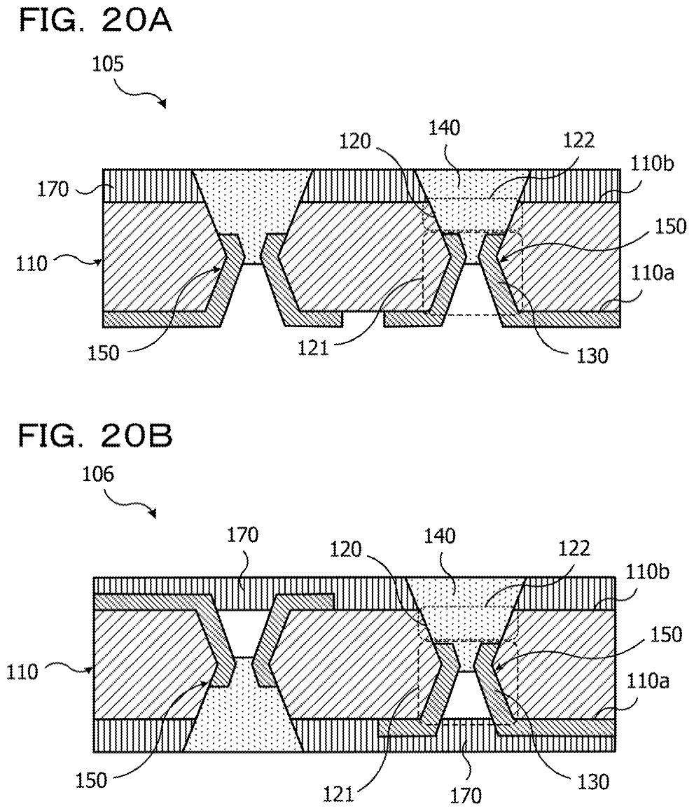

FIGS. 20A and 20B are diagrams for describing a fifth modification of the substrate according to the second embodiment. FIGS. 20A and 20B each schematically illustrate an enlarged sectional view of a principal portion of an example of a substrate.

A substrate 105 illustrated in FIG. 20A has a structure in which the via 150 including the metal layer 130 provided in the portion 121 of the through hole 120 and the conductive layer 140 provided in the portion 122 of the through hole 120 to be coupled to the metal layer 130 is provided at a plurality of positions in the glass layer 110. Also with the structure of the substrate 105, the same actions and effects as those described for the via 150 of the substrate 100 may be obtained for the via 150 of each position.

A substrate 106 illustrated in FIG. 20B has a structure in which the via 150 in which the conductive layer 140 is provided on the surface 110b side and the via 150 in which the conductive layer 140 is provided on the surface 110a side, which is an opposite side, are provided at different positions in the glass layer 110. Such a substrate 106 is obtained by forming one via 150 in one position in the glass layer 110 in the steps of FIGS. 8A to 10C and inverting the surfaces 110b and 110a and forming the other via 150 in a different position in the glass layer 110 in accordance with the example of steps illustrated in FIGS. 8A to 10C. Also with the structure of the substrate 106, the same actions and effects as those described for the via 150 of the substrate 100 may be obtained for the via 150 of each position.

### Third Embodiment

Various electronic components such as semiconductor chips may be mounted over the substrates 1, 100, 101, 102, 103, 104, 105, and 106 described in the first and second embodiments and a multilayer substrate including at least one of these.

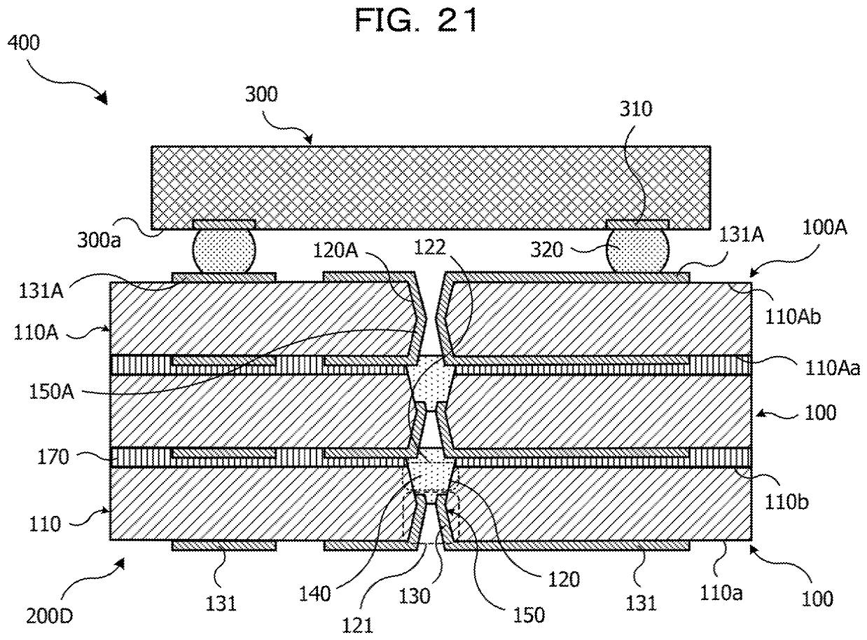

FIG. 21 is a diagram for describing an example of an electronic device according to a third embodiment. FIG. 21 schematically illustrates a cross-sectional view of a principal part of an example of an electronic device.

As an example, FIG. 21 illustrates an electronic device 400 in which a semiconductor chip 300 is mounted as an electronic component over a multilayer substrate 200D including the substrates 100 and the substrate 100A described in the second embodiment above.

The multilayer substrate 200D has a structure in which two substrates 100 and further one substrate 100A are laminated with adhesive layers 170 therebetween. The multilayer substrate 2000 is formed by a batch lamination process. The semiconductor chip 300 is a semiconductor chip such as a large-scale integration (LSI) chip, and includes electrodes 310 at one surface 300a thereof. In the semiconductor chip 300, the surface 300a at which the electrodes 310 are provided is positioned to face the multilayer substrate 200D side, and the electrodes 310 are coupled to the wiring layers 131A provided over the uppermost substrate 100A of the multilayer substrate 200D via bumps 320 formed from solder or the like.

As described above, in the electronic device 400, the substrate 100 in which the metal layer 130 is provided in a part (portion 121) of the through hole 120 and the conductive layer 140 is provided in the other part (portion 122) of the through hole 120 to be coupled to the metal layer 130 is used for the multilayer substrate 200D over which the semiconductor chip 300 is mounted. In such a multilayer substrate 200D, even when heat generated by operation of the semiconductor chip 300 is transmitted thereto, stress generated in the glass layer 110 around the through hole 120 is relieved by the conductive layer 140 provided in the part of the substrate 100. Further, with the substrate 100, the conductive layer 140 thermally expanding is pressed against the metal layer 130, and thus an increase in the coupling resistance therebetween and occurrence of coupling failure therebetween may be suppressed. As a result of this, the substrate 100 having high conduction reliability and the multilayer substrate 200D including the substrate 100 may be realized in which cracks in the glass layer 110, snapping caused by the cracks, and the like may be suppressed and an increase in the coupling resistance between and occurrence of coupling failure between the conductive layer 140 and the metal layer 130 may be suppressed. The semiconductor chip 300 is mounted over such a multilayer substrate 200D, and thereby the electronic device 400 having high performance and high reliability may be realized.

Although an example in which the one semiconductor chip 300 is mounted over the multilayer substrate 200D has been described, a plurality of semiconductor chips of the same or different types may be mounted over the multilayer substrate 200D. The electronic component is not limited to a semiconductor chip, and various electronic components such as a resistor, a capacitor, and an inductor may be mounted over the multilayer substrate 200D.

Although the multilayer substrate 200D including the substrate 100 has been described as an example herein, various electronic components such as the semiconductor chip 300 may be also mounted over the substrates 1, 100, 101, 102, 103, 104, 105, and 106 and various multilayer substrates including at least one of these.

### Fourth Embodiment

The substrates 1, 100, 101, 102, 103, 104, 105, and 106 described in the first and second embodiments above, the electronic device 400 described in the third embodiment above, and the like may be provided in various electronic apparatuses (also referred to as “electronic devices”). For example, the substrates 1 and 100 to 106, the electronic device 400, and the like may be provided in various electronic apparatuses such as a computer (a personal computer, a super computer, a server, or the like), a smartphone, a mobile phone, a tablet terminal, a sensor, a camera, an audio device, a measuring device, an inspection device, and a manufacturing device.

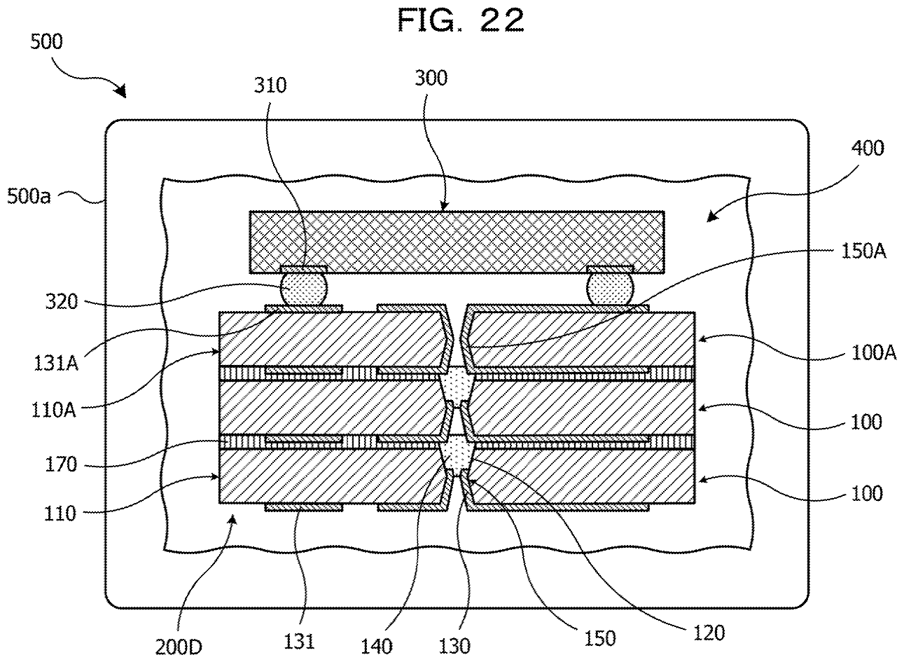

FIG. 22 is a diagram for describing an example of an electronic apparatus according to a fourth embodiment. FIG. 22 schematically illustrates a cross-sectional view of a principal part of an example of the electronic apparatus.

As illustrated in FIG. 22, for example, the electronic device 400 as described in the third embodiment above is provided (incorporated) in a housing 500a of an electronic apparatus 500 of a certain type. The electronic device 400 may be accommodated in a rack or a slot provided in the electronic apparatus 500.

As described above, in the electronic device 400, the substrate 100 in which the metal layer 130 is provided in a part of the through hole 120 and the conductive layer 140 is provided in the other part of the through hole 120 to be coupled to the metal layer 130 is used for the multilayer substrate 200D. As a result of this, the substrate 100 having high conduction reliability and the multilayer substrate 200D including the substrate 100 may be realized in which cracks in the glass layer 110, snapping caused by the cracks, and the like may be suppressed and an increase in the coupling resistance between and occurrence of coupling failure between the conductive layer 140 and the metal layer 130 may be suppressed. The semiconductor chip 300 is mounted over such a multilayer substrate 200D, and thereby the electronic device 400 having high performance and high reliability may be realized. Such an electronic device 400 is mounted, and the electronic apparatus 500 having high performance and high reliability may be realized.

Although the electronic device 400 has been described as an example herein, the substrates 1, 100, 101, 102, 103, 104, 105, and 106 and various multilayer substrates including at least one of these, and various electronic devices in which various electronic components such as the semiconductor chip 300 are mounted over the substrates may be similarly provided in various electronic apparatuses.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A substrate comprising:
a glass layer having a first surface, a second surface opposite to the first surface, and a through hole penetrating between the first surface and the second surface;
a metal layer provided in a first portion of the through hole, the first portion extending from the first surface and not reaching the second surface; and
a conductive layer provided in a second portion of the through hole, coupled to the metal layer, and containing a resin and a conductive filler, the second portion extending from the second surface and not reaching the first surface.

2. The substrate according to claim 1, wherein the metal layer is provided over an inner wall of the through hole.

3. The substrate according to claim 2, wherein the conductive layer contains the conductive filler that is larger than an opening surrounded by the metal layer.

4. The substrate according to claim 1, further comprising an insulating layer provided over the second surface, wherein
the conductive layer projects from the second layer to penetrate through the insulating layer and has a higher thermal expansion coefficient than the insulating layer.

5. The substrate according to claim 1 comprising a plurality of first substrates that are laminated and each include the glass layer, the metal layer, and the conductive layer.

6. The substrate according to claim 1 comprising:
a first substrate including the glass layer, the metal layer, and the conductive layer; and
a second substrate that is laminated on the second surface side of the glass layer of the first substrate and includes a conductive coupling portion coupled to the conductive layer.

7. A method of manufacturing a substrate, the method comprising:
preparing a glass layer having a first surface, a second surface opposite to the first surface, and a through hole penetrating between the first surface and the second surface;
forming a metal layer in a first portion of the through hole, the first portion extending from the first surface and not reaching the second surface; and
forming, in a second portion of the through hole, a conductive layer coupled to the metal layer and containing a resin and a conductive filler mixed with the resin, the second portion extending from the second surface and not reaching the first surface.

8. The method according to claim 7, further comprising:
laminating a second substrate including a conductive coupling portion on the second surface side of the glass layer of a first substrate including the glass layer, the metal layer, and the conductive layer; and
coupling the conductive layer to the conductive coupling portion.

9. An electronic device comprising:
a substrate including
a glass layer having a first surface, a second surface opposite to the first surface, and a through hole penetrating between the first surface and the second surface,
a metal layer provided in a first portion of the through hole, the first portion extending from the first surface and not reaching the second surface, and
a conductive layer provided in a second portion of the through hole, coupled to the metal layer, and containing a resin and a conductive filler mixed with the resin, the second portion extending from the second surface and not reaching the first surface; and
an electronic component mounted over the substrate.

10. The electronic device according to claim 9, wherein the metal layer is provided over an inner wall of the through hole.

11. The electronic device according to claim 10, wherein the conductive layer contains the conductive filler that is larger than an opening surrounded by the metal layer.

12. The electronic device according to claim 9, wherein the substrate further includes an insulating layer provided over the second surface, wherein
the conductive layer projects from the second layer to penetrate through the insulating layer and has a higher thermal expansion coefficient than the insulating layer.

13. The electronic device according to claim 9, wherein the substrate further includes a plurality of first substrates that are laminated and each include the glass layer, the metal layer, and the conductive layer.

14. The electronic device according to claim 9, wherein the substrate further includes:
a first substrate including the glass layer, the metal layer, and the conductive layer; and
a second substrate that is laminated on the second surface side of the glass layer of the first substrate and includes a conductive coupling portion coupled to the conductive layer.
